(19) United States
(12) Patent Application Publication
(10) Pub. No.: US 2024/0193330 A1
(43) Pub. Date: Jun. 13, 2024

(54) WORK SUPPORT APPARATUS AND WORK SUPPORT METHOD

(71) Applicant: Hitachi, Ltd., Tokyo (JP)

(72) Inventors: Takaaki UENO, Tokyo (JP); Shoji YAMAMOTO, Tokyo (JP); Shingo HAYASHI, Tokyo (JP); Masahiko NIIOKA, Tokyo (JP)

(21) Appl. No.: 18/470,773

(22) Filed: Sep. 20, 2023

(30) Foreign Application Priority Data
Dec. 12, 2022 (JP) 2022-197986

(51) Int. Cl. G06F 30/31; G06Q 10/0633

(52) U.S. Cl. CPC G06F 30/31; G06Q 10/0633

(57) ABSTRACT

A work support apparatus includes a line and point detection unit that acquires drawing data in which a circuit indicating a connection relationship between devices is described by a character, a line, and a point, and detects the line and point based on the drawing data. A drawing sign detection unit detects a drawing sign constituting the circuit. The wiring detection unit detects a wiring connecting the drawing signs based on information on the line and point. The character detection unit detects the character. The circuit connection information generation unit generates circuit connection information. Since the circuit connection information in the same page and over pages of the drawing data is generated, the terminal component detection unit detects, as a terminal component, a wiring or first drawing sign that is not connected to a second drawing sign at least at one end.

### CROSS-REFERENCE TO RELATED APPLICATION

This application claims priority pursuant to 35 U.S.C. § 119 from Japanese Patent Application No. 2022-197986, filed on Dec. 12, 2022, the entire disclosure of which is hereby incorporated herein by reference.

### BACKGROUND OF THE INVENTION

### 1. Field of the Invention

The present invention relates to a computer technique for supporting site work of a worker.

### 2. Description of Related Art

In Japan, a population decline due to an increase in average life and a decline in birth rate, and a decline in labor population due to the declining birth rate and aging population have become social problems. Under such circumstances, in order to compensate for the decline in the labor population, a simple manual work may be automated by a machine to improve efficiency of the work. However, in a work type requiring a skilled work, it is difficult to simply automate the work since a high site skill for performing the complicated work is required. Therefore, it is necessary to create a mechanism for efficiently performing the skilled work within a limited labor force, and an example thereof includes a mechanism in which a manual including skilled know-how is created based on work data of a skilled engineer and anyone can perform the skilled work regardless of skills using the manual.

As an example of the skilled work, there is work using a circuit drawing (hereinafter, referred to as “drawing work”). In the drawing work, a conduction state and a sequence operation of a circuit are confirmed using a drawing describing information on electrical connection between components constituting the circuit (hereinafter, referred to as “circuit connection information”), and a corresponding portion (that is, corresponding connection information) on the drawing is painted by handwriting. In the drawing work, in order to create a manual including know-how of a skilled engineer, it is necessary to use a wearable terminal such as an electronic paper or a tablet to acquire handwriting by a worker as time-series data, and analyze the time-series handwritten data. Specifically, a work order obtained by comparing the handwritten data on the drawing with the circuit connection information on a back side thereof is analyzed. Here, the circuit connection information specifically refers to connection information on a drawing sign representing each component constituting the circuit by a symbol on the drawing, and a wiring indicating wire connection.

Data describing the circuit connection information may be, for example, computer aided design (CAD) drawing data, but in many cases, the wearable terminal used by the worker at a work site does not have a processing capability capable of displaying the CAD drawing data. Therefore, when the drawing data is displayed on the wearable terminal, the CAD drawing data is converted into a data format that can be displayed by the terminal, for example, portable document format (PDF) drawing data. However, when the data format is converted from CAD to PDF, since a circuit part is converted into line and character data on the PDF drawing data, the circuit connection information is lost. When the drawing work is performed using the PDF drawing data and the handwritten data is analyzed, it is necessary to generate the circuit connection information based on the drawing data including the line and the character data.

Since it is difficult to describe all the circuit connection information on one page when the circuit is large in scale, in order to divide the circuit halfway and describe a subsequent part of the circuit in another area of the same page or another page, the circuit connection information is described over a plurality of pages including at least the same page (hereinafter, also simply referred to as “a plurality of pages”). Therefore, in generating the circuit connection information based on the drawing data, it is a problem to generate the circuit connection information over the plurality of pages accurately as intended by a designer even for a broken circuit.

PTL 1 discloses a technique of generating connection information for representing a structure using two neural networks (NNs) with a subject of “accurately generating data on the structure based on a drawing of the structure on paper”. In PTL 1, an imaged drawing is input to the first NN, and coordinates of points representing a column core or a beam core of the structure and coordinates of a line representing a column or a beam connecting the points are recognized according to a probability of being output from the NN. Point and line data is input to the second NN, a probability of two points where a starting point and an ending point of a line are connected is output to the NN, and coordinates of the two points having a maximum probability are reset. There is disclosed a technique of generating point and line connection information using the two NNs, by recognizing the point and line at positions further away from each other by the first NN and resetting the coordinates by the second NN even when there is a break.

### CITATION LIST

### Patent Literature

PTL 1: JP2020-187541A

### SUMMARY OF THE INVENTION

The technique disclosed in PTL 1 uses the NN to generate the connection information on drawing components indicating detection of the drawing component and the break. Therefore, when the technique disclosed in PTL 1 is applied to the drawing work described above, since the connection information is generated based on the probability of being output from the NN, there is a high possibility that erroneous connection information is generated when an unlearned pattern is input to the NN. If the erroneous connection information is generated, a work order cannot be correctly analyzed when the connection information is compared with handwritten data.

In view of the above problems, an object of the invention is to provide a technique capable of accurately generating circuit connection information over a plurality of pages based on drawing data including line and character data.

A work support apparatus according to the invention includes a line and point detection unit, a drawing sign detection unit, a wiring detection unit, a character detection unit, a circuit connection information generation unit, and a terminal component detection unit. The line and point detection unit acquires drawing data in which a circuit indicating a connection relationship between devices is described by a character, a line, and a point, and detects the line and point based on the drawing data. The drawing sign detection unit detects a drawing sign constituting the circuit. The wiring detection unit detects a wiring connecting the drawing signs based on information on the line and point. The character detection unit detects the character. The circuit connection information generation unit generates circuit connection information by extracting information on contact of the drawing sign with the wiring on the drawing data based on coordinate data on the drawing sign and the wiring included in the same page of the drawing data. Since the circuit connection information in the same page and over pages of the drawing data is generated, the terminal component detection unit detects, as a terminal component, a wiring or a first drawing sign that is not connected to a second drawing sign at least at one end based on the circuit connection information generated by the circuit connection information generation unit.

Problems disclosed in the present application and a solution method therefor will be apparent from sections of embodiments for carrying out the invention, and the drawings.

According to the invention, it is possible to accurately generate the circuit connection information over the plurality of pages based on the drawing data including line and character data.

### BRIEF DESCRIPTION OF THE DRAWINGS

FIG. 1 is a functional block diagram of a work support apparatus according to a first embodiment.

FIG. 2 is a flowchart showing an operation of the work support apparatus according to the first embodiment.

FIG. 3A is a diagram showing an example of a terminal component.

FIG. 3B is a diagram showing an example of the terminal component.

FIG. 4A is a diagram showing an example of output data of a drawing component detection unit 103.

FIG. 4B is a diagram showing an example of the output data of the drawing component detection unit 103.

FIG. 4C is a diagram showing an example of the output data of the drawing component detection unit 103.

FIG. 5 is a diagram showing an example of output data of a circuit connection information generation unit 108.

FIG. 6A is a diagram showing examples of drawing data after a terminal component detection unit 109 detects a terminal component.

FIG. 6B is a diagram showing examples of drawing data after the terminal component detection unit 109 detects a terminal component.

FIG. 7 is a flowchart showing a method for detecting a terminal wiring by the terminal component detection unit 109.

FIG. 8A is a diagram showing a method for associating a terminal wiring with a wiring name by a terminal component name assigning unit 110.

FIG. 8B is a diagram showing the method for associating the terminal wiring with the wiring name by the terminal component name assigning unit 110.

FIG. 8C is a diagram showing the method for associating the terminal wiring of the wiring name by the terminal component name assigning unit 110.

FIG. 9 is a flowchart showing a method for generating connection information on a terminal component by a terminal component connection information generation unit 111.

FIG. 10A is a diagram showing an example of output data of the terminal component connection information generation unit 111.

FIG. 10B is a diagram showing an example of the output data of the terminal 1 component connection information generation unit 111.

FIG. 11A is a diagram showing an example of work analysis by a work analysis unit 113.

FIG. 11B is a diagram showing an example of the work analysis by the work analysis unit 113.

FIG. 11C is a diagram showing an example of the work analysis by the work analysis unit 113.

FIG. 12 is a functional block diagram of a work support apparatus according to a second embodiment.

FIG. 13 is a flowchart showing an operation of the work support apparatus according to the second embodiment.

FIG. 14A is a diagram showing an example of a link sign.

FIG. 14B is a diagram showing an example of the link sign.

FIG. 15A is a diagram showing an advantage of using the link sign.

FIG. 15B is a diagram showing an advantage of using the link sign.

FIG. 15C is a diagram showing an advantage of using the link sign.

FIG. 16 is a flowchart showing an operation of a link sign detection unit 1200.

FIG. 17 is a flowchart showing a sheet link grouping method by the link sign detection unit 1200.

FIG. 18 is a diagram showing a method for registering a sheet link present in a table by the link sign detection unit 1200.

FIG. 19A is a diagram showing a step of detecting a coordinate supplement link by the link sign detection unit 1200.

FIG. 19B is a diagram showing a step of detecting the coordinate supplement link by the link sign detection unit 1200.

FIG. 20A is a diagram showing a method for connecting a terminal component of a terminal component link sign connection information generation unit 1201 to a link sign.

FIG. 20B is a diagram showing the method for connecting the terminal component of the terminal component link sign connection information generation unit 1201 to the link sign.

FIG. 21 is a functional block diagram of a work support apparatus according to a third embodiment.

FIG. 22 is a flowchart showing an operation of the work support apparatus according to the third embodiment.

FIG. 23A is a diagram showing a specific example of assigning a hyperlink by a hyperlink assigning unit 2100.

FIG. 23B is a diagram showing a specific example of assigning a hyperlink by the hyperlink assigning unit 2100.

### DESCRIPTION OF EMBODIMENTS

In the following description, an “interface device” may be one or more interface devices. The one or more interface devices may be at least one of the following devices.
One or more input and output (I/O) interface devices. An input and output (I/O) interface device is an interface device for at least one of an I/O device and a remote display computer. The I/O interface device for the display computer may be a communication interface device. At least one I/O device may be a user interface device, for example, an input device such as a keyboard and a pointing device, or an output device such as a display device.
One or more communication interface devices. The one or more communication interface devices may be one or more communication interface devices of the same type (for example, one or more network interface cards (NICs)) or two or more communication interface devices of different types (for example, a NIC and a host bus adapter (HBA)).

In the following description, a “memory” may be one or more memory devices, which is an example of one or more storage devices, and may typically be a main storage device. At least one memory device in the memory may be a volatile memory device or a non-volatile memory device.

In the following description, a “persistent storage device” may be one or more persistent storage devices, which is an example of one or more storage devices. The persistent storage device may typically be a non-volatile storage device (for example, an auxiliary storage device), and specifically, for example, a hard disk drive (HDD), a solid state drive (SSD), a non-volatile memory express (NVME) drive, or a storage class memory (SCM).

In the following description, a “storage device” may be at least one of a memory and a persistent storage device.

In the following description, a “processor” may be one or more processor devices. At least one processor device may typically be a microprocessor device such as a central processing unit (CPU), and may also be a processor device of another type such as a graphics processing unit (GPU). At least one processor device may be a single core or a multi-core. At least one processor device may be a processor core. At least one processor device may be a processor device in a broad sense, such as a circuit (for example, a field-programmable gate array (FPGA), a complex programmable logic device (CPLD), or an application specific integrated circuit (ASIC)), which is an aggregate of gate arrays in a hardware description language that performs a part or all of processing.

In the following description, the expression “yyy unit” may be used to describe a function. The function may be implemented by a processor executing one or more computer programs, or may be implemented by one or more hardware circuits (for example, an FPGA or an ASIC), or may be implemented by a combination thereof. When the function is implemented by a processor executing a program, the function may be at least a part of the processor since predetermined processing is executed by appropriately using a storage device and/or an interface device. The processing described with the function as a subject may be processing executed by a processor or an apparatus including the processor. The program may be installed from a program source. The program source may be, for example, a program distribution computer or a computer-readable recording medium (for example, a non-transitory recording medium). The description for each function is an example, and a plurality of functions may be combined into one function, or one function may be divided into a plurality of functions.

In the following description, processing may be described with a “program” as a subject, but the processing described with the program as the subject may be processing executed by a processor or an apparatus including the processor. Two or more programs may be implemented as one program, or one program may be implemented as two or more programs.

In the following description, the expression “xxx table” may be used to describe information for acquiring an output for an input. The information may be a table of any structure, or may be a learning model that generates an output for an input, such as a neural network, a genetic algorithm, and a random forest. Therefore, the “xxx table” can be referred to as “xxx information”. In the following description, a configuration of each table is an example, and one table may be divided into two or more tables, or all or a part of the two or more tables may be one table.

In the following description, a “work support apparatus” may be an apparatus or a system including one or more physical computers, or may be a system (for example, a cloud computing system) implemented on a physical computing resource group (for example, a cloud infrastructure). To “display” display information by the work support apparatus may be to display the display information on a display device of a computer, or to transmit the display information from a computer to a display computer (in the latter case, the display information is displayed by the display computer).

Hereinafter, several embodiments will be described.

In the following description, the same or similar components are denoted by the same reference numerals, and redundant description may be omitted.

When a plurality of elements having the same or similar functions are present, the same reference numerals may be denoted by different subscripts in order to distinguish the plurality of elements. On the other hand, when it is not necessary to distinguish the plurality of elements, the description may be made by omitting the subscripts.

### First Embodiment

In a first embodiment, a component name present around a drawing component is used to detect a terminal component that is a drawing component indicating a break and accurately generate connection information on the terminal component, thereby generating circuit connection information over a plurality of pages. Hereinafter, the first embodiment will be described in detail.

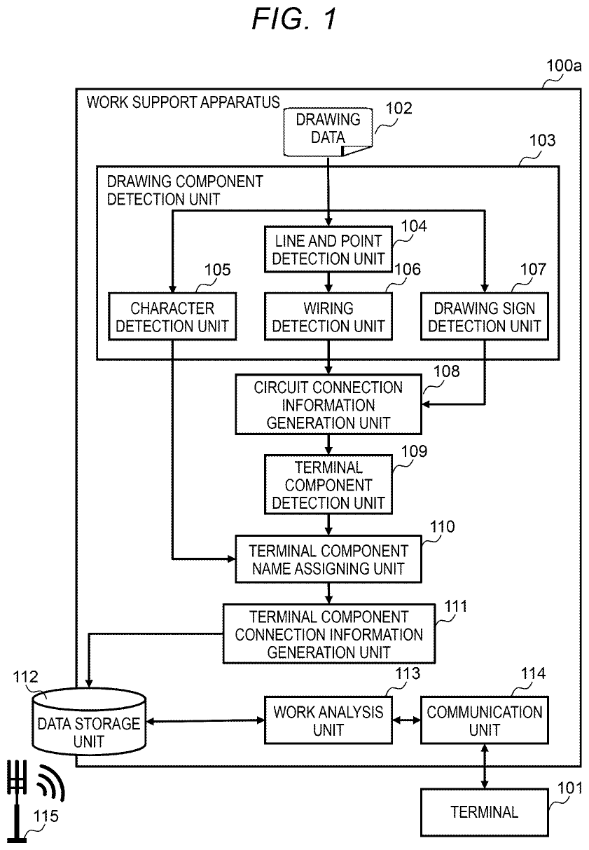

FIG. 1 is a functional block diagram of a work support apparatus 100a according to the first embodiment of the invention. The work support apparatus 100a shown in FIG. 1 is connected to a terminal 101 to be used by a worker who is a user of the work support apparatus 100a via an appropriate communication network such as the Internet or a dedicated line so as to enable data communication therebetween. Examples of the terminal 101 include wearable terminals such as electronic paper and tablets. When the user performs handwriting on a screen of the terminal 101 using an electronic pen or the like, the terminal 101 records the handwriting as time-series data.

Although FIG. 1 shows only one terminal 101, data may be transmitted to and received from several hundred terminals 101a, 101b, 101c, . . . , 101n. In FIG. 1, the work support apparatus 100a, a data storage unit 112, and the terminal 101 are shown as being spatially connected in a wired manner, but the work support apparatus 100a, the data storage unit 112, and the terminal 101 may be in spatially different locations and perform data communication via a network by a data base station 115 or the like.

### Configuration of Work Support Apparatus 100a

Next, a configuration example of the work support apparatus 100a according to the embodiment will be described. The work support apparatus 100a is implemented by a computer device or a server device having configurations to be described later.

Further, as shown in FIG. 1, the work support apparatus 100a is also connected to the data base station 115 via an appropriate communication network such as the Internet or a dedicated line so as to be enable data communication therebetween. The work support apparatus 100a, the terminal 101, and the data base station 115 are connected to the communication network by wire via a well-known communication device (not shown), and may be connected wirelessly.

The work support apparatus 100a is implemented by one general-purpose computer device. In the following description, the work support apparatus 100a is assumed to be implemented by one general-purpose computer device including one or more processors, one or more storage devices, one or more interface devices, and a wired or wireless communication line connecting these above.

That is, the work support apparatus 100a includes a storage device including a persistent storage device and a memory, an interface device, and a processor connected to the storage device and the interface device.

The persistent storage device is an auxiliary storage device including a non-volatile storage element such as a flash memory. Specific examples of the persistent storage device include a solid state drive (SSD) and a hard disk drive (HDD). The persistent storage device stores at least a program. The program is a computer program for implementing necessary functions as the work support apparatus 100a.

When the program is executed by the processor, various types of processing for work support are executed (details will be described later).

The program may be installed from a program source. The program source may be, for example, a program distribution computer or a computer-readable recording medium. The program may be implemented by a device driver, an operating system, various application programs located in an upper layer thereof, or a library that provides a common function to the programs. Further, two or more programs may be implemented as one program, or one program may be implemented as two or more programs.

The persistent storage device controls a data storage unit 112 to be described later by storing various data.

The memory is a main storage device mainly including a volatile storage element such as a random access memory (RAM). The memory temporarily holds data representing various types of information read from the persistent storage device and various data acquired from the terminal 101 and the data base station 115.

The processor is a processor device such as a central processing unit (CPU) and various co-processors. The processor performs overall control on the work support apparatus 100a itself by calling a program into a memory and executing the program, and controls a control unit that executes various types of processing such as arithmetic processing and determination processing.

The interface device includes a communication interface device that is connected to a communication network and communicates with the terminal 101 and the data base station 115, and an I/O interface device.

Next, an example of blocks of various functions provided in the work support apparatus 100a according to the embodiment will be described. Each block to be described below indicates a block of a functional unit instead of a configuration of a hardware unit.

The work support apparatus 100a includes functional blocks: a drawing component detection unit 103 that detects a drawing component based on drawing data 102 including line and character data; a circuit connection information generation unit 108 that generates circuit connection information based on the detected drawing component; a terminal component detection unit 109 that detects a terminal component that is a drawing component indicating a break based on the generated circuit connection information; a terminal component name assigning unit 110 that assigns a name by associating a component name with the detected terminal component; a terminal component connection information generation unit 111 that identifies a connection target of the terminal component to which the name is assigned, generates connection information on the terminal component, and generates connection information of pieces of circuit connection information associated with the terminal component; the data storage unit 112 that stores the drawing data 102 including the circuit connection information generated based on the connection information on the terminal component, and data after work analysis; a work analysis unit 113 that analyzes the circuit connection information on which work is performed and a work order by comparing handwritten data on a screen of the terminal 101 with position coordinates in the generated circuit connection information; a communication unit 114 that receives data from the terminal 101 and transmits data to the terminal 101; a control unit (not shown); and a user interface unit (not shown).

Here, the drawing component is, for example, a wiring, a drawing sign, or a character. The wiring is a conductive wire that connects drawing signs included in a circuit in the drawing data. The drawing sign is a sign (for example, an electric drawing sign defined in JIS C 0617) representing a component constituting the circuit by a symbol on the drawing data. The character is present around the wiring and the drawing sign included in the drawing data 102, and indicates additional information such as a name and an attribute. The circuit connection information indicates connection information on the wiring and the drawing sign. Details will be described later. The terminal component indicates a wiring or drawing sign, which is not connected to another drawing sign at least at one end out of end points of the terminal component. Details will be described later.

The drawing component detection unit 103 includes a line and point detection unit 104 that detects a line and a point based on the drawing data 102 and outputs line and point data, a character detection unit 105 that detects a character and outputs character data, a wiring detection unit 106 that detects a wiring based on the line and point data and outputs wiring data, and a drawing sign detection unit 107 that detects a drawing sign and outputs drawing sign data. Details of each output data will be described later.

The data storage unit 112 is implemented using, for example, a storage device including a persistent storage device and a memory, and stores a program for supplying various processing instructions to the control unit, and data representing various types of information to be used in processing executed by the control unit. The control unit can execute various types of processing for work support by reading information from the storage unit and writing information to storage unit.

The communication unit 114 is in charge of communication processing with other devices such as the terminal 101 and the data base station 115 executed via the Internet (an example of the communication network). The communication unit 114 is implemented using, for example, a network interface (NIC) or a host bus adapter (HBA).

The control unit executes various types of data processing based on a user operation input detected by the user interface unit, data acquired by the communication unit 114, and the program and data stored in the data storage unit 112. The control unit also functions as an interface of the user interface unit, the communication unit 114, and the data storage unit 112.

The control unit is implemented using a processor, and can implement each of the above-described functional blocks by executing a predetermined program. The control unit may be implemented using a logic circuit such as a field programmable gate array (FPGA) instead of the processor. The control unit may be implemented by a combination of a processor and a logic circuit.

The user interface unit receives an input operation from the user and is in charge of processing related to a user interface, such as image display and audio output. The user interface unit has functional blocks that are an input unit and an output unit. The input unit detects various operations from the user. The input unit is implemented using, for example, a keyboard, a pointing device, or a touch panel. The output unit displays various screens on a display device and outputs audio. The output unit includes, for example, a liquid crystal display or a touch screen.

That is, components of the work support apparatus 100a are implemented by hardware including a storage device such as a processor, a memory, or a persistent storage device, and a wired or wireless communication line or an interface device that couples these above, and software that is stored in the storage device and supplies a processing instruction to an arithmetic unit.

In the embodiment, a case where functions of the work support apparatus 100a are integrally implemented by one computer device has been described. However, these functions may be implemented by a plurality of interconnected computer devices or server devices. The work support apparatus 100a may include a general-purpose computer device such as a laptop PC and a web browser installed in the general-purpose computer device, or may include a web server and various portable devices.

The description for each function is an example, and a plurality of functions may be combined into one function, or one function may be divided into a plurality of functions. The configuration of the work support apparatus 100a has been described above.

### Operation of Work Support Apparatus 100a

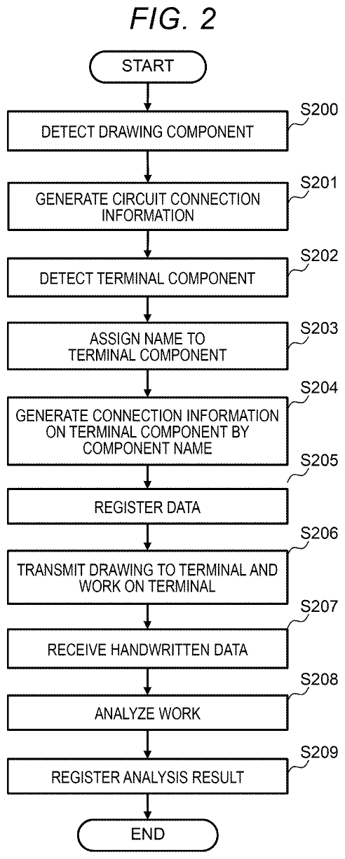

Next, an operation of the work support apparatus 100a according to the first embodiment will be described with reference to a flowchart shown in FIG. 2. When the drawing data 102 including line and character data is received, a wiring, a drawing sign, and a character are detected (step S200), and circuit connection information that is connection information on the wiring and the drawing sign is generated (step S201). A terminal component that is not connected to a drawing sign at least at one end is detected based on the generated circuit connection information (step S202), and a name is assigned to the detected terminal component in association with a component name present around the terminal component (step S203). Since a drawing component present on the drawing data 102a is uniquely named, a connection target of the terminal component is uniquely identified by searching for a drawing component having the same name, and connection information on the terminal component is generated to generate circuit connection information over a plurality of pages (step S204). The drawing data 102 including the generated circuit connection information is registered in the data storage unit 112 (step S205), and transmitted to the terminal 101 via the communication unit 114, and the drawing data 102 including the generated circuit connection information is displayed on a screen of the terminal 101 for the worker to perform work (step S206). After the work is completed, the work support apparatus 100a receives handwritten data from the terminal 101 via the communication unit 114 (step S207), analyzes the work by comparing the handwritten data on the screen of the terminal 101 with position coordinates in the generated circuit connection information on a back side thereof (step S208), and registers an analysis result in the data storage unit 112 (step S209). The operation of the work support apparatus 100a according to the first embodiment has been described above.

### Terminal Component

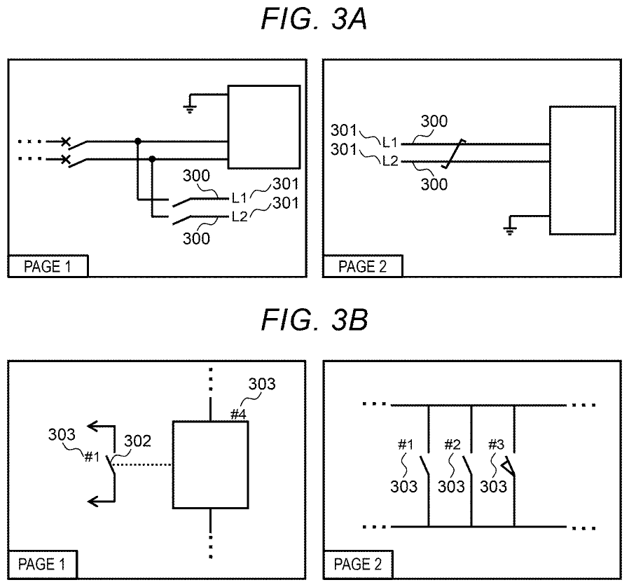

Next, the terminal component will be described with reference to examples shown in FIGS. 3A and 3B. As described above, although electrical connection information (circuit connection information) between components constituting a circuit is described in a circuit drawing, since it is difficult to describe all the circuit connection information on one page when the circuit is large in scale, in order to divide the circuit halfway and describe a subsequent part of the circuit in another area of the same page or another page, the circuit connection information is described over a plurality of pages. The terminal component is a drawing component indicating a circuit break on the drawing data, and refers to the drawing component that is not connected to a drawing sign at least at one end. An example of the terminal component includes a terminal wiring having connection information in which an end point of the terminal wiring is connected to another end point of another terminal wiring as shown in FIG. 3A, and a terminal drawing sign having connection information in which a drawing sign is connected to another drawing sign as shown in FIG. 3B. On the drawing data, since each drawing component is uniquely named, the terminal component also has a name. When the circuit is divided halfway, drawing components having the same name are divided, and thus drawing components (that is, terminal components) including end points having the same name are present in pairs on the drawing data and have connection information. For example, FIG. 3A shows an example in which a terminal wiring 300 having L1 as a wiring name 301 has connection information on pages 1 and 2, and a terminal wiring 300 having a name L2 as the wiring name 301 has connection information on pages 1 and 2, and FIG. 3B shows an example in which a terminal drawing sign having #1 as drawing sign name 303 in page 1 has connection information with a drawing sign having #1 as the drawing sign name 303 in page 2. The terminal component has been described above.

### Output Data of Drawing Component Detection Unit 103

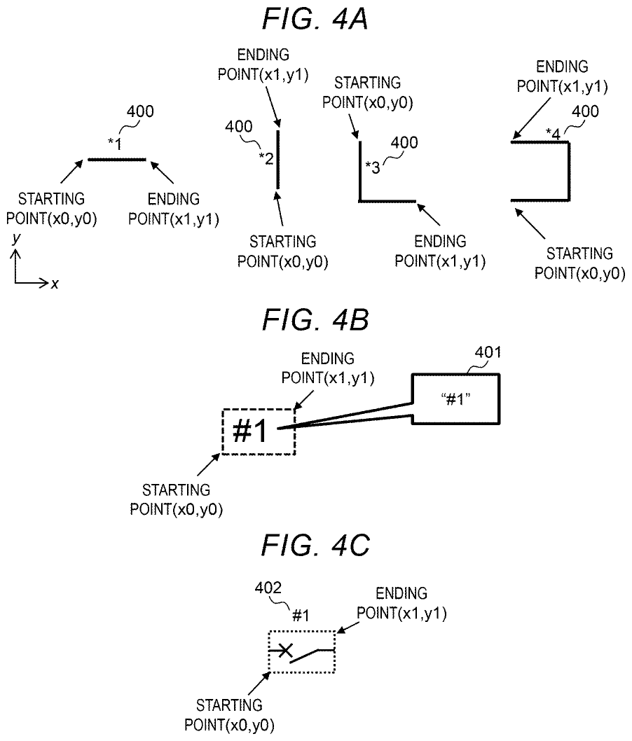

Next, wiring data, character data, and drawing sign data output by the drawing component detection unit 103 will be described with reference to FIGS. 4A to 4C. First, the wiring data will be described. FIG. 4A is an example of the wiring data. The wiring data includes at least a unique wiring index 400 (for example, an index “*1”), coordinate information (for example, a starting point (x0, y0) and an ending point (x1, y1)), and a page number. Lines in contact are coupled to form one wiring. The wiring index 400 is held as internal data for processing.

One of two end points is a starting point, and the other is an ending point. For example, among the two end points, when a leftward direction and a rightward direction as the drawing is viewed from a front side are referred to as a −X direction and a +X direction, respectively, the starting point and the ending point are close to the −X direction and the +X direction, respectively. In a case where X coordinates of the end points coincide with each other, hereinafter, when an upward direction and a downward direction as the drawing is viewed from the front side are referred to as a +Y direction and a −Y direction, respectively, the starting point and the ending point are close to the −Y direction and the +Y direction, respectively. The wiring data has been described above.

Next, the character data will be described. FIG. 4B is an example of the character data. The character data includes at least character information 401 (for example, character information “#1”), coordinate information (for example, a starting point (x0, y0) at the lower left of a rectangle indicating a character area and an ending point (x1, y1) at the upper right thereof), and a page number. The character data has been described above.

Next, the drawing sign data will be described. FIG. 4C is an example of the drawing sign data. The drawing sign data includes at least a unique drawing sign name 402 (for example, a drawing sign name “#1”), coordinate information (for example, a starting point (x0, y0) at the lower left of a rectangle indicating a drawing sign area, an ending point (x1, y1) at the upper right thereof), and a page number. The drawing sign data has been described above. Supplement of Operation of Drawing Sign Detection Unit 107

As described above, the drawing sign data includes the unique drawing sign name 402, but when a circuit part includes line and character data as in PDF drawing data, it is necessary to associate the detected drawing sign with a character representing a drawing sign name present therearound. Association processing is executed together with detection of the drawing sign by the drawing sign detection unit 107. Specific contents of the association processing will be described below. Since a character representing a drawing sign name is often described at a position closest to a drawing sign area, a character closest to a detected drawing sign may be associated with the drawing sign during association. In addition, at that time, association accuracy can be improved by following a drawing data creation rule. For example, when the rule is to describe a drawing sign name on the upper left of a drawing sign area as the drawing is viewed from the front side, a character area having a smallest distance from the upper left of a rectangle of the drawing sign area to the lower right of a rectangle of the character area may be associated. The processing when the drawing sign and the component name are associated by the drawing sign detection unit 107 has been described above.

### Output Data of Circuit Connection Information Generation Unit 108

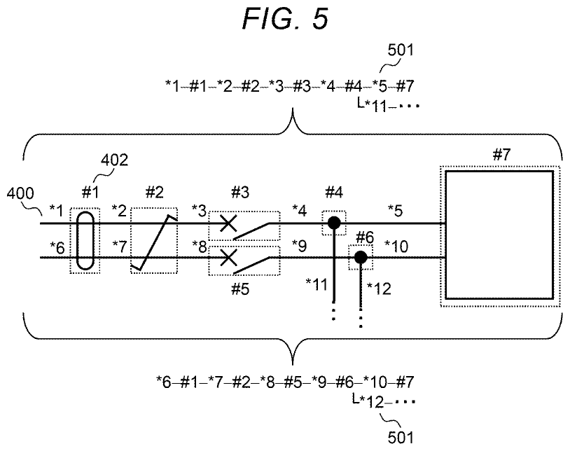

Next, circuit connection information data output by the circuit connection information generation unit 108 will be described with reference to FIG. 5. Circuit connection information 501 refers to connection information in which a wiring and a drawing sign included in the same page are spatially connected. Seven drawing signs with drawing sign names 402 from #1 to #7 and 12 wirings with wiring indexes 400 from *1 to *12 are shown in an example in FIG. 5. The circuit connection information data includes connection information on at least a wiring having the unique wiring index 400 and a drawing sign having the unique drawing sign name 402. For example, connection information in which wirings and drawing signs are repeatedly and alternately connected, such as *1-#1-*2-#2-*3, . . . , as shown in FIG. 5. As long as the connection information can be expressed, any data format such as a list type or JavaScript (registered trademark) Object Notation (JSON) may be used. The circuit connection information data output by the circuit connection information generation unit 108 has been described above. Operation of Terminal Component Detection Unit 109

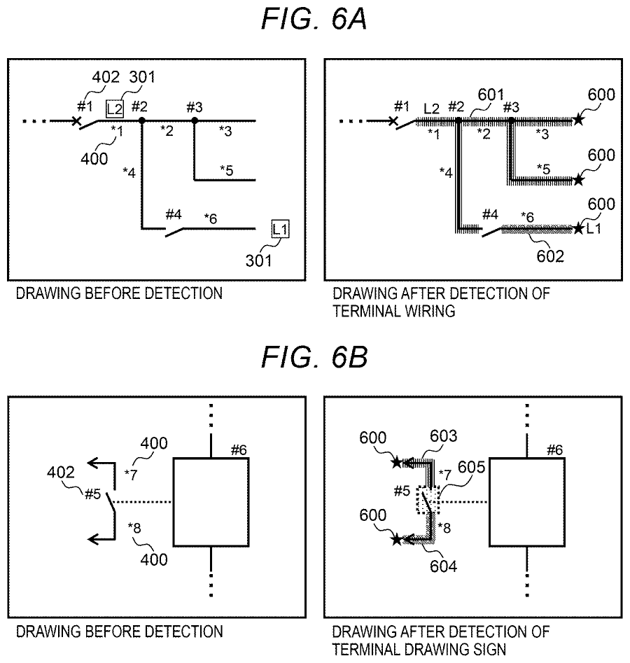

Next, operation contents of the terminal component detection unit 109 will be described with reference to examples of drawing data shown in FIGS. 6A and 6B. The terminal component detection unit 109 detects a terminal component based on the wiring index 400 unique to each wiring and drawing data in which a unique name is assigned to each drawing sign. First, detection of a terminal wiring will be described below with reference to FIG. 6A. FIG. 6A shows an example of drawing data before detection of the terminal wiring and an example of drawing data after detection of the terminal wiring. In the first embodiment, since connection information on a terminal component is generated by using a component name (wiring name), it is necessary to associate the detected terminal wiring with a character representing the wiring name 301 present therearound. Therefore, in the terminal component detection unit 109, it is not only necessary to simply detect a wiring including an end point but also to detect a terminal wiring so as to be easily associated with the wiring name 301. As shown in the example of the drawing data before the detection of the terminal wiring in FIG. 6A, a position of the wiring name is not necessarily present in the vicinity of an end point 600, but is present somewhere in electrically equal wirings. In FIG. 6A, a wiring group 601 with “*1, *2, *3, *4, and *5” and a wiring group 602 with “*6” are electrically equal wirings to which the same wiring name is assigned. As described above, in detecting the terminal wiring by the terminal component detection unit 109, in order to facilitate association with the wiring name, “the wirings including the end point 600” and “electrically equal wirings are appropriately grouped” are detected as the terminal wiring based on the drawing data to which the unique wiring index 400 is attached. A detailed method of grouping will be described later. The detection of the terminal wiring has been described above.

Next, detection of a terminal drawing sign will be described below with reference to FIG. 6B. FIG. 6B shows an example of drawing data before detection of a terminal drawing sign 605 and an example of drawing data after detection of the terminal drawing sign 605. As shown in FIG. 6B, in the terminal drawing sign 605, two terminal wirings each having an arrow at one end are often connected to a terminal of a drawing sign representing a contact point such as a “contact point a”. A reason why the number of contact points is large in the terminal drawing sign 605 is that when connection of a contact point in the circuit and a contact point in the device is shown, information in the drawing data is excessive, and thus in many cases, only the contact point is shown in another area in the drawing data by omitting wire connection. Arrow data is output from the drawing sign detection unit 107, and includes at least a unique drawing sign name, coordinate information indicating an area, and a page number. Whether the terminal wiring has an arrow can be determined based on whether the terminal wiring is in contact with an arrow area. Even when one end has an arrow, the arrow is regarded as an end point if the arrow is not connected to another drawing sign. In FIG. 6B, a drawing sign #5 connected to the terminal wiring, that is, an electrically equal wiring group 603 and an electrically equal wiring group 604 is the terminal drawing sign 605. The detection of the terminal drawing sign 605 has been described above.

### Wiring Grouping Method by Terminal Component Detection Unit 109

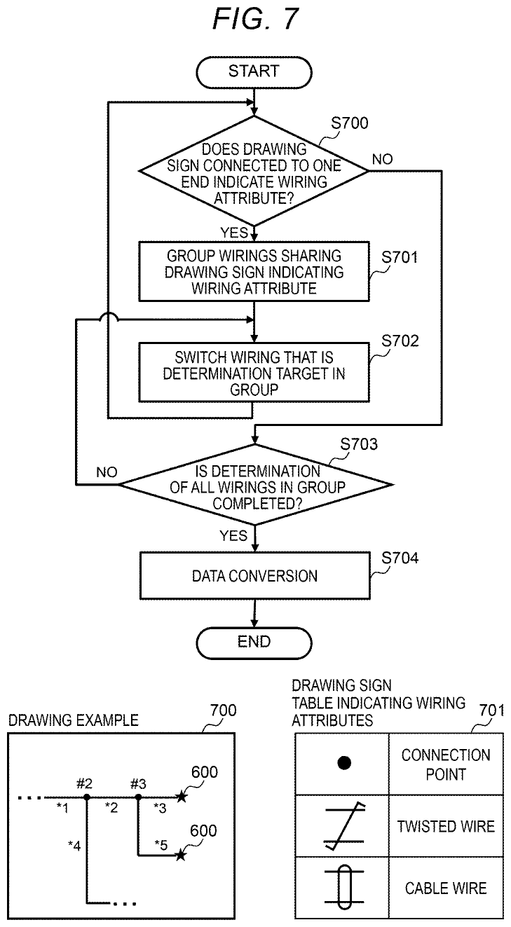

Next, a method for appropriately grouping electrically equal wirings as the terminal wirings described above will be described with reference to FIG. 7. FIG. 7 shows a flowchart of grouping, a drawing data example 700 including a terminal wiring, and a drawing sign table 701 indicating wiring attributes used for the grouping. Since the wiring is a conductive wire that connects drawing signs included in the circuit in the drawing data, a drawing sign is provided between the wirings. Therefore, even when the drawing sign is provided between the wirings, electrically equal wirings are appropriately grouped. Specifically, it is determined whether to perform grouping based on an attribute of the drawing sign present between the wirings. Among the drawing signs, since the drawing sign indicating the wiring attribute indicates a shape and characteristics of the wiring, the wirings sharing the drawing sign can be regarded as having the same electric potential and can be grouped. Examples of the drawing sign indicating the wiring attribute include a “connection point”, a “twisted wire”, and a “cable wire” defined in JIS C 0617 as shown in the drawing sign table 701 in FIG. 7.

Hereinafter, a grouping method will be described using the flowchart shown in FIG. 7 and the drawing data example 700. FIG. 7 is a flow of outputting a result (that is, a terminal wiring) obtained by grouping wirings having the same electric potential as an input wiring when a wiring having an end point is input. First, when the wiring having the end point is input (*3 is input in the drawing data example 700), it is determined whether a drawing sign connected to one end of the input wiring indicates a wiring attribute (step S700) (in the drawing data example 700, since #3 is a drawing sign indicating a wiring attribute, “YES” is determined). When “YES” is determined in step S700, wirings sharing the drawing sign indicating the wiring attribute are grouped (step S701) (in the drawing data example 700, *2 and *5 sharing #3 are grouped), a target wiring in step S700 is switched in the group (step S702), and it is determined again whether a condition of step S700 is satisfied. Here, when the determination in step S700 is performed again, the drawing sign used for grouping once is excluded (when a determination target is switched to *5 in the drawing data example 700, since a drawing sign indicating a wiring attribute other than #3 used for grouping once is not connected, “NO” is determined). When “NO” is determined in step S700, it is determined whether all the wirings in the group are determination targets in step S700. (Step S703) (in the drawing data example 700, when *3, *2, and *5 belong to a group of electrically equal wirings, and *5 is already a determination target in step S700, since *2 is not yet a determination target, “NO” is determined). In step S703, when “NO” is determined, a target wiring is switched in step S702, and the determination in step S700 is performed (in the drawing data example 700, when the target is switched to *2 in step S702, since #2 corresponds to a drawing sign indicating a wiring attribute, “YES” is determined in step S700, and *1 and *4 sharing #2 are grouped). In step S703, when “YES” is determined, a group of electrically equal wirings grouped together is converted into data as a terminal wiring. The data includes, at least, a unique index for the terminal wiring, coordinate information on an end point, and connection information in which each wiring constituting the group is spatially connected to a drawing sign indicating a wiring attribute. The above processing is executed on wirings having all the end points included in the drawing data. The grouping method has been described above.

### Operation of Terminal Component Name Assigning Unit 110

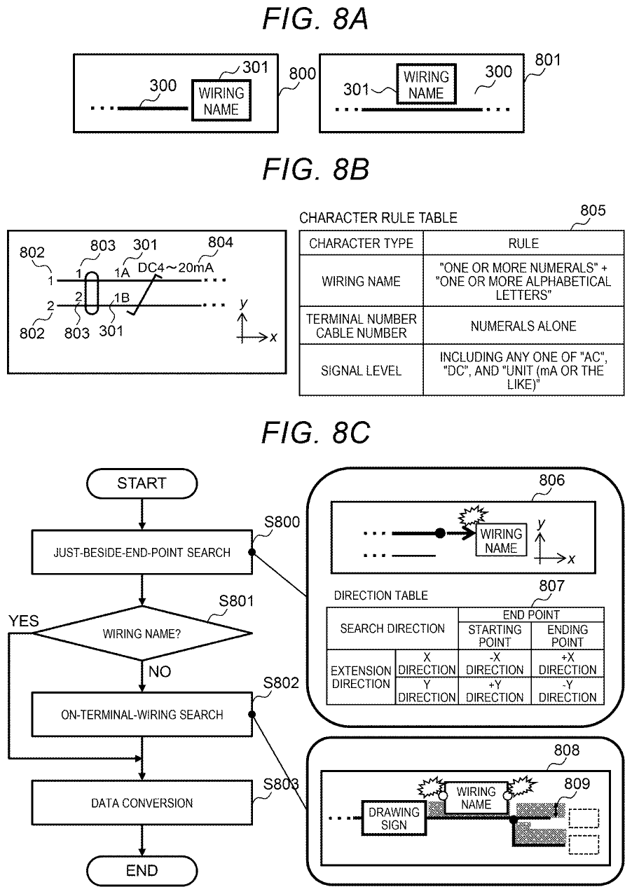

Next, an operation of the terminal component name assigning unit 110 will be described with reference to FIG. 8. The terminal component name assigning unit 110 associates the terminal component detected by the terminal component detection unit 109 with a component name present around the terminal component. An example in which a wiring name is associated with a terminal wiring will be described below as a specific example. FIG. 8A shows an example of a positional relationship between a terminal wiring and a wiring name. The positional relationship between the terminal wiring and the wiring name is roughly classified into two types as shown in FIG. 8A. There is a case where the wiring name is present just beside an end point as shown in a positional relationship pattern 800 and a case where the wiring name is present on the terminal wiring as shown in a positional relationship pattern 801 (that is, on the wiring of an electrically equal wiring group). As shown in FIG. 8B, a plurality of characters other than the wiring name are present around the terminal wiring. For example, there is a terminal number 802 that is often written just beside an end point, a cable number 803 that is often written around a drawing sign indicating a “cable wire”, and a signal level 804 that is often described around a wiring. Since the characters are noise when associating the terminal wiring with the wiring name, it is necessary to appropriately associate the wiring name with the terminal wiring even when there is noise. When a drawing designer describes characters in drawing data, the drawing designer often follows a predetermined description rule for each character type in order to prevent the worker from erroneously recognizing a character type as another character type when viewing the drawing data. For example, as in a character rule table 805 shown in FIG. 8B, the wiring name is “one or more numerals”+“one or more alphabetical letters”, the terminal number 802 and the cable number 803 are “numerals alone”, and the signal level 804 is “characters including any one of ‘AC’, ‘DC’, and ‘unit (mA or the like)’”. Therefore, when associating the terminal wiring with the wiring name, it is possible to perform the association with high accuracy by associating only the characters that match the description rule of the wiring name among the characters that match the two types of positional relationship patterns (800, 801).

Hereinafter, a method for associating a terminal wiring with a wiring name will be described with reference to a flowchart shown in FIG. 8C. FIG. 8C is a flow of outputting data on a terminal wiring having an associated wiring name when data of the terminal wiring is input. As described above, since there are two types of positional relationship patterns (800, 801) for the terminal wiring and the wiring name, first, a character present just beside the end point in the positional relationship pattern 800 is searched for (step S800). In step S800, a character is searched for by extending a line from the end point by a predetermined length. Here, the predetermined length is set at, for example, a maximum width of a character area described in a circuit area included in the drawing data. This is because the wiring name is often included within the maximum width of the character area from the end point. In step S800, a search direction follows a direction table 807 determined by a “type of end point (starting point and ending point)” and an “extension direction of the wiring including the end point among the wirings constituting the terminal wiring” since the wiring name is present just beside the end point (for example, when the end point is the “ending point” and the extension direction is an “x direction” as shown in a just-beside-end-point search example 806 in FIG. 8C, the line for search is extended in the +X direction). Regarding the character area where a length between the extended line and a center of the character area is the smallest in step S800, it is determined whether character information included in the character area satisfies the description rule of the wiring name (step S801), and when “YES” is determined, the wiring name is assigned to the input data on the terminal wiring and converted into data (step S803). When “NO” is determined in step S801, a character present on the terminal wiring in the other positional relationship pattern 801 is searched for (step S802). In step S802, as shown in an on-terminal-wiring search 808 in FIG. 8C, example a predetermined width 809 is added in a direction orthogonal to an extension direction of the wirings constituting the terminal wiring, and only a character that is related to character information on a character area sharing at least a part of the predetermined width 809 and matches the description rule of the wiring name is associated as the wiring name. Here, the predetermined width 809 can be a search range of a lowest limit according to a minimum height width (1.8 mm) of characters that can be described on a drawing defined in JIS Z 8313-5:2000, the number of characters included in the predetermined width 809 can be reduced, and search efficiency can be improved. After the association with the wiring name in step S802, the processing proceeds to step S803. The operation of the terminal component name assigning unit 110 has been described above.

### Operation of Terminal Information Component Connection Information Generation Unit 111

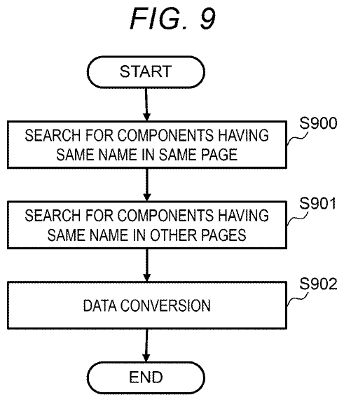

Next, an operation of the terminal component connection information generation unit 111 will be described with reference to a flowchart shown in FIG. 9. In the first embodiment, the terminal component connection information generation unit 111 identifies the connection target of the terminal component using the component name assigned to the terminal component, and generates the connection information on the terminal component. Since the connection target of the terminal component has the same component name, drawing components having the same component name are searched for in the page or another page. When the search is performed using the component name, in particular, in a case of the terminal wiring, a plurality of terminal wirings having the same wiring name may be present. This is because many power supply wirings and the like from a power supply are present, but wirings commonly used over a plurality of pages are present. Accordingly, even when the drawing components having the same component name are present in the plurality of pages, it is necessary to generate the connection information on the terminal component as intended by the designer.

Hereinafter, a method for searching for drawing components having the same component name will be described with reference to FIG. 9. FIG. 9 is a flow of outputting connection information on a terminal component when data on the terminal component having a component name is input. Here, the data of the terminal component having the component name is input in order from data included in a first page. Since there may be a connection target in a page including the input terminal component, drawing components having the same name are searched for in the page (step S900). Next, whether the drawing components having the same component name are present in other pages are searched for page by page in ascending order from a page including the input terminal component (step S901). Here, a reason why the pages are searched in ascending order is to improve processing efficiency without repeatedly generating connection information on the terminal component already generated in a previous page since the connection information is generated in order from a first page. Next, in step S902, connection information on the input terminal component and the drawing components having the same component name searched for in step S900 and S901 is generated. Details of connection information data generated in step S902 will be described later. Here, when there are a plurality of connection targets for one terminal component, connection information may be generated for each of a plurality of connection targets. According to the above flow, even when a plurality of drawing components having the same component name are present, the connection information on the terminal component can be generated. The operation of the terminal component connection information generation unit 111 has been described above.

### Output Data of Terminal Component Connection Information Generation Unit 111

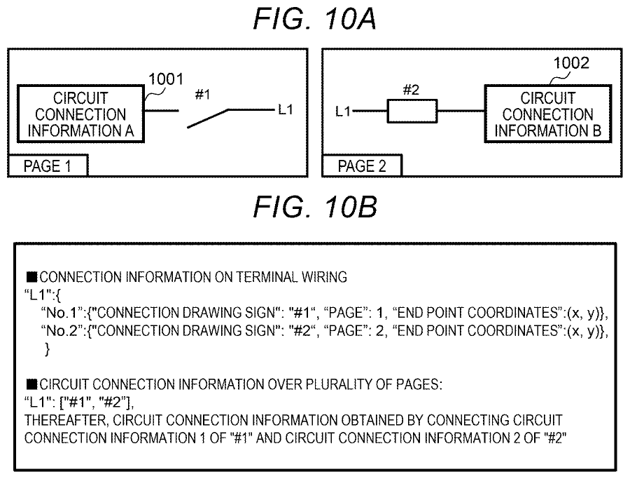

Next, data on connection information on a terminal component output by the terminal component connection information generation unit 111 will be described with reference to FIGS. 10A and 10B. FIG. 10A is an example of drawing data in which a terminal wiring has connection information, and shows the example in which the terminal wiring having a wiring name L1 has connection information on pages 1 and 2. Page 1 has the terminal wiring L1, a drawing sign #1, and circuit connection information A1001 as connection information, and page 2 has the terminal wiring L1, a drawing sign #2, and circuit connection information B1002 as connection information. FIG. 10B shows an example in which the connection information of the example of the drawing data shown in FIG. 10A is converted into data. As described above, since the wiring is a conductive wire indicating connection between drawing signs, the connection information on the terminal component at least includes a wiring name of the terminal wiring, a drawing sign name connected to one end, a page number, coordinate information on an end point (described in No. 1 in FIG. 10B), a drawing sign name connected to the other end, a page number, and coordinate information on an end point (described in No. 2 in FIG. 10B). Since the page number immediately refers to the page including the connection information, the coordinate information on the end point can be used to distinguish the connection information on each end point when the terminal wiring has a plurality of end points. When the connection information can be generated, circuit connection information over a plurality of pages can be generated. For example, in FIG. 10B, the drawing sign #1 on page 1 and the drawing sign #2 on page 2 can be connected, and the circuit connection information A1001 connected to the drawing sign #1 and the circuit connection information B1002 connected to the drawing sign #2 can be connected.

An example of data on connection information on a terminal wiring has been described above, but in a case of data of connection information on a terminal drawing sign, since the terminal drawing sign corresponds to a connection drawing sign as shown in FIG. 10B, at least a drawing sign name of the terminal drawing sign, a page number and coordinates of a drawing sign area at one end, and a page number and coordinates of a drawing sign area at the other end are included. The data on the connection information on the terminal component output by the terminal component connection information generation unit 111 has been described above.

### Examples of Work Analysis by Work Analysis Unit 113

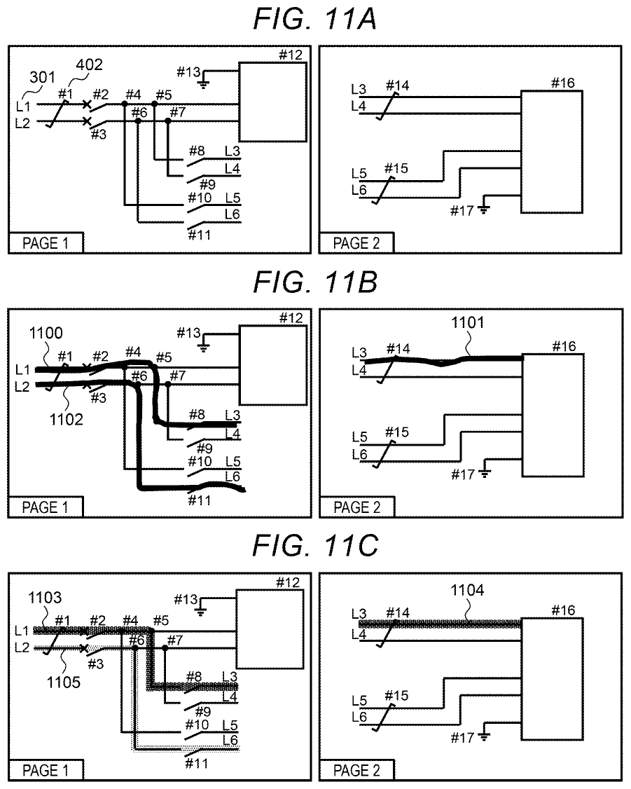

Next, specific examples of work analysis by the work analysis unit 113 will be described with reference to examples of drawing data shown in FIGS. 11A to 11C. FIG. 11A shows an example of drawing data before work. This is an example in which terminal wirings having wiring names L3, L4, L5, and L6 have connection information over pages 1 and 2. FIG. 11B shows an example of drawing data after work using the terminal 101. As described above, in drawing work, after a conduction state and a sequence operation of a circuit are confirmed, the corresponding connection information on drawing data is painted by handwriting, and thus the handwritten data is recorded in time series on the drawing data as evidence of work. An actual state of the handwritten data is point cloud data obtained by sampling a handwritten one-stroke path at a frequency unique to the terminal 101. In the example of the drawing data in FIG. 11B, handwritten data 1100 recorded at a time point t1, handwritten data 1101 recorded at a time point t2, and handwritten data 1102 recorded at a time point t3 are shown. FIG. 11C shows an example of drawing data after work analysis. By comparing the handwritten data with coordinate information in the connection information on a back side thereof, it is possible to analyze “checked connection information and that time point” and a “work order”. For example, when the “checked connection information and that time point” are known, the checked connection information such as connection information 1103 checked at the time point t1, connection information 1104 checked at the time point t2, and connection information 1105 checked at the time point t3 as shown in the example of the drawing data in FIG. 11C can be highlighted. The “work order” refers to an order in which handwritten point cloud data is generated, thereby knowing the work order in the checked connection information. For example, when the handwritten data 1100 at the time point t1 is one stroke from the −X direction to the +X direction, it is known that the connection information 1103 checked at the time point t1 is confirmed in an order of L1→#1→#2→#4→#5→#8→L3.

When circuit connection information over a plurality of pages can be generated, the work can be analyzed more specifically based on the order of page transition. For example, in FIG. 11C, the connection information of L1→#1→#2→#4→#5→#8→L3→#14→#16 is provided from the −X direction, but when the work is performed in an order of time point t1→t2→t3, it is known that the page is transitioned in an order of page 1→page 2→page 1. Therefore, it is known that after the work at the time point t1 (L1→#1→#2→#4→#5→#8→L3), the connection information (L3→#14→#16) continued to page 2 is confirmed before the other connection information included in page 1 is confirmed.

The highlighting on the drawing data is also advantageous. When the check of the connection information over a plurality of pages is completed and when the check is not completed, a manner of highlighting (for example, color or shading of color) on the drawing data is changed. In the example in FIG. 11C, the work performed at the time points t1 and t2 is highlighted in a dark color since the connection information is checked over the plurality of pages, and the work performed at the time t3 is highlighted in a light color since the connection information over a second page is not checked but only in a first page. By visualizing a check completion state of the connection information in the next and subsequent pages in this manner, the check state can be determined at a glance, which is useful for improving work efficiency and eliminating work omission. In addition, the uncompleted part of the work can be fed back to the worker. The example of the work analysis by the work analysis unit 113 has been described above.

### Second Embodiment

In a second embodiment of the invention, a connection target of a terminal component is identified using a link sign present around the terminal component, and connection information on the terminal component is generated. Details of the link sign will be described later, and the link sign is a character, a number, or a sign representing a “page” or a “location (hereinafter, referred to as “coordinates”)” of an end point where the connection target is present. Hereinafter, the second embodiment will be described in detail.

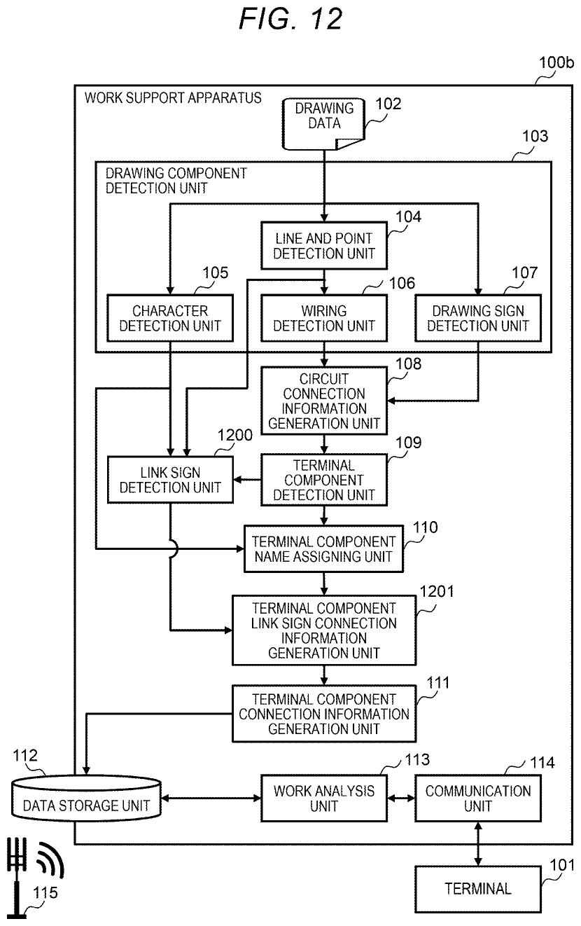

FIG. 12 is a functional block diagram of a work support apparatus 100b according to the second embodiment of the invention. Compared with the functional block diagram according to the first embodiment shown in FIG. 1, a link sign detection unit 1200 and a terminal component link sign connection information generation unit 1201 are added. Hereinafter, the description of blocks common in processing to the first embodiment will be omitted, and an operation of the work support apparatus 100b according to the second embodiment, the details of the link sign, an advantage of using the link sign, an operation of the link sign detection unit 1200, and an operation of the terminal component link sign connection information generation unit 1201 will be described in this order.

### Operation of Work Support Apparatus 100b according to Second Embodiment

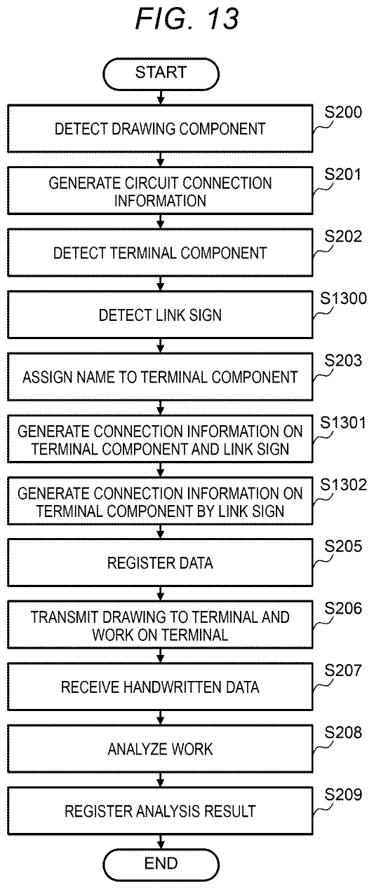

First, the operation of the work support apparatus 100b according to the second embodiment will be described with reference to a flowchart shown in FIG. 13. Compared with the flowchart according to the first embodiment shown in FIG. 2, two steps of detecting a link sign (step S1300) and generating connection information on a terminal component and the link sign (step S1301) are added, and generating the connection information on the terminal component by a component name (step S204) is replaced with generating the connection information on the terminal component by the link sign (step S1302). Hereinafter, the same steps as those according to the first embodiment are denoted by the same reference numerals, the description thereof will be omitted, and only different steps will be described below.

After detecting the terminal component (step S202), the link sign present in drawing data is detected based on results of detecting a drawing component (step S200) and detecting the terminal component (step S202) (step S1300). After step S1300, a component name is assigned to the terminal component (step S203), and after the component name is assigned, the link sign present around the terminal component is connected and information on the link sign is attached (step S1301). Since a “page” where a connection target is present and specific “coordinates” in the page are known based on the information on the link sign attached to the terminal component, the drawing component having information on the corresponding link sign is searched for, the connection information on the terminal component is generated, and circuit connection information over a plurality of pages is generated (step S1302). The operation different from that of the work support apparatus 100a according to the first embodiment, among various operations performed by the work support apparatus 100b according to the second embodiment, has been described above.

Details of Link sign

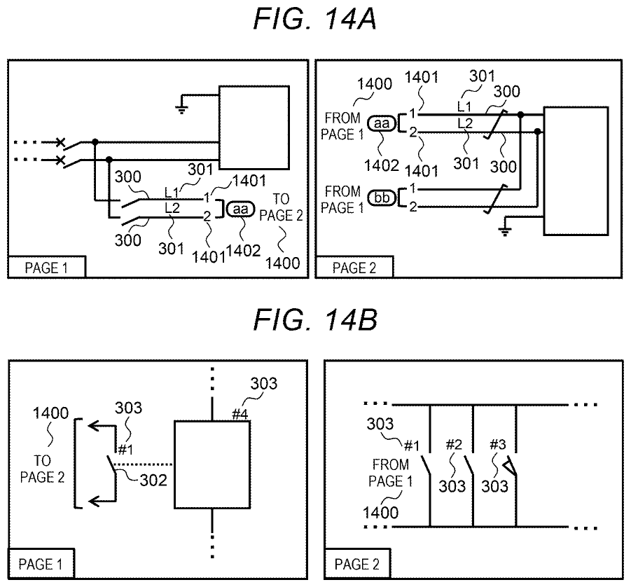

Next, the link sign will be described in detail with reference to FIGS. 14A and 14B. In addition to the component name, the link sign may be described around the terminal component such that the worker can easily identify the connection target of the terminal component by viewing the drawing data. In the second embodiment, the connection information on the terminal component is generated using the link sign. FIG. 14A shows an example in which link signs are described around the terminal wiring L1 and around the terminal wiring L2, and FIG. 14B shows an example in which a link sign is described around the terminal drawing sign #1. Hereinafter, in the second embodiment, there are three types of link signs, that is, a sheet link 1400, a coordinate link 1401, and a coordinate supplement link 1402, and a link sign having a property of always uniquely determining a connection target by a combination of the three types will be described as an example.

First, the sheet link 1400 will be described. The sheet link 1400 is a character, a number, or a sign representing a “page” where a connection target is present. For example, “to page 1” including at least a page number, “to sheet AAA” by replacing a page number with a sheet name, or “★” often includes a predetermined key word such as “page” or “sheet”. FIG. 14A is the example in which the sheet link 1400 includes a page number, and it can be known that a connection target of the terminal wirings L1 and L2 is on “page 2” using the sheet link 1400 “to page 2” in page 1.

Next, the coordinate link 1401 will be described. The coordinate link 1401 is a character, a number, or a sign representing specific “coordinates” where a connection target is present in a page, for example, 1, (1), (A), (a), ( [symbol] ), ※1, ※A, or “▴”. As shown in FIG. 14A, the coordinate link is often described just beside an end point, and when the coordinate link 1401 “1” present just beside an end point of the terminal wiring L1 in page 1 is used in combination with the sheet link 1400 “to page 2”, it is known that a connection target of the terminal wiring L1 is a terminal wiring having “1” in page 2. Here, since a component name present around a terminal component can be regarded as having the same role as the coordinate link 1401, the component name can be handled as the coordinate link as necessary.

Next, the coordinate supplement link 1402 will be described. When a unique character is not used for the coordinate link 1401, a connection target may not be uniquely determined by a combination of the sheet link 1400 and the coordinate link 1401. For example, in FIG. 14A, two terminal wirings having “1” in “page 2” are present. The coordinate supplement link 1402 is a character, a number, or a sign for supplementing the coordinate link 1401 in order to uniquely determine the connection target in the above case. For example, in (1), (a), or an ellipse, a character such as “aa” is often surrounded by a circle or an ellipse. As shown in FIG. 14A, the coordinate supplement link is often described around a side of the coordinate supplement link 1402, and when the coordinate supplement link 1402 “‘aa’ in the ellipse” present just beside the end point of the terminal wiring L1 in the page 1 is used in combination with the sheet link 1400 “to page 2” and the coordinate link 1401 “1”, it is known that a connection target of the terminal wiring L1 is a terminal wiring having “1” and “aa” in the ellipse in “page 2”, and the connection target can be uniquely determined. The link sign has been described above.

### Advantages of Using Link Sign

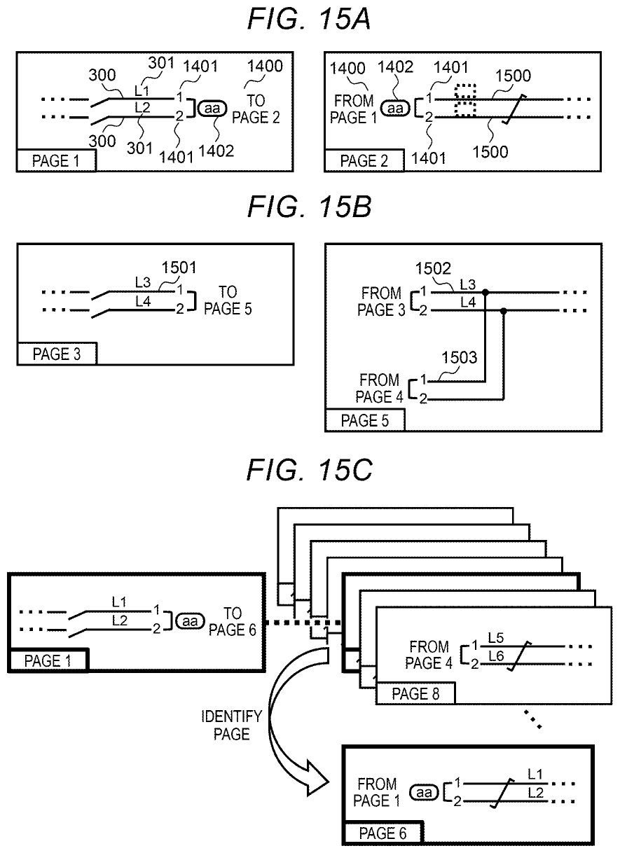

Next, advantages of using the link sign will be described with reference to FIGS. 15A to 15C. There are three advantages of using the link sign as follows.

A first point is that connection information on a terminal component can be generated even when a component name is not described on drawing data. The component name may be omitted in order to prevent excessive information of the drawing data due to a limitation in description space for the drawing data or repeated description of the component name. In such a case, in the first embodiment, it is difficult to generate the connection information since the component name cannot be assigned to the terminal component. On the other hand, when the link sign is described around the terminal component, the connection target of the terminal component can be identified based on the information on the link sign, and thus the connection information on the terminal component can be generated even when there is no component name. In addition, when the component name is described for one terminal component and no component name is described for the other drawing component, the component name can be assigned to the other drawing component after the connection information is generated. For example, FIG. 15A shows an example in which L1 and L2 are described around a terminal wiring as the wiring name 301 in page 1, but a terminal wiring 1500 without description of a wiring name is included in page 2. By using the link sign, for example, it is known that the terminal wiring L1 in page 1 may be connected to the terminal wiring having “1” and “aa” in “page 2”. In addition, the wiring name “L1” can be assigned to the terminal wiring without description of wiring names having “1” and “aa” in “Page 2”.

A second point is that a connection target of a terminal component can be uniquely and correctly determined. Mainly in the terminal wiring, when a plurality of end points are included in the terminal wiring, component names are the same, but a plurality of candidates of connection targets may be present. In such a case, in the first embodiment, the connection target is estimated and determined based on a positional relationship, but the connection target can be uniquely determined using a link sign. For example, FIG. 15B shows an example of drawing data in which the terminal wirings L3 and L4 have connection information over page 3 and page 5, but when the terminal wiring L3 in page 3 is considered as a connection source 1501, the terminal wiring L3 in the page 5 can be identified by searching for a connection target by a component name, but it is difficult to reliably determine which of a connection target candidate 1502 and a connection target candidate 1503 is correct. On the other hand, using the link sign, it is known that the connection target candidate 1502 having “1” in “page 3” is a correct connection target.

A third point is that processing of searching for a connection target of a terminal component can be speeded up. When searching for a drawing component having a component name as in the first embodiment, since the search is sequentially performed in units of pages, the search may take time. On the other hand, since a “page” where a connection target is present can be uniquely identified using a link sign, the connection target may be searched for only in the target page, the search time is shortened, and the search processing can be speeded up. For example, as shown in FIG. 15C, when the connection target of the terminal wiring L1 included in page 1 is searched for, it is known that the page including the connection target is and only page 6 may be set as a search target. The three advantages of using the link sign have been described above.

### Operation of Link Sign Detection Unit 1200

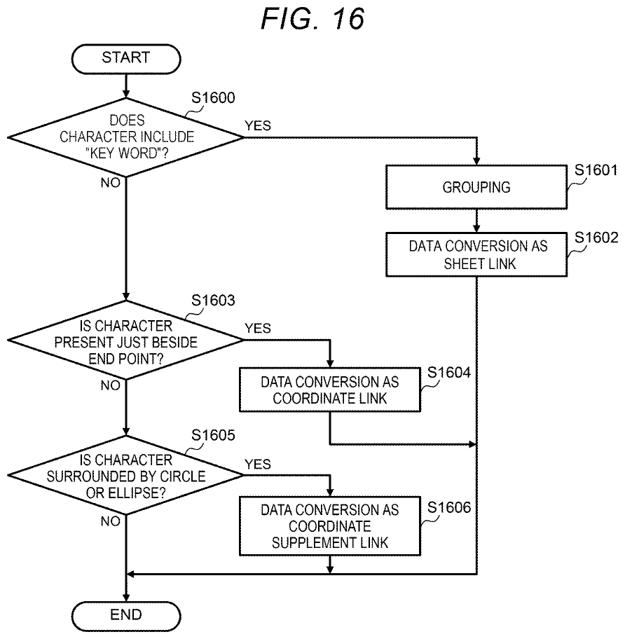

Next, the operation of the link sign detection unit 1200 will be described with reference to a flowchart shown in FIG. 16. FIG. 16 is a flow of inputting character data, line and point data output from the drawing component detection unit 103, and terminal component data output from the terminal component detection unit 109, and outputting data on a sheet link, a coordinate link, and a coordinate supplement link. A flow of performing data conversion in an order of the sheet link, the coordinate link, and the coordinate supplement link is shown as an example. First, in step S1600, it is determined whether a key word of the sheet link is included (step S1600). As described above, since the sheet link often includes a predetermined key word such as “sheet” or “page”, it is determined whether the predetermined key word is included in character information. When “YES” is determined, since there is a high possibility of being a sheet link, a plurality of pieces of character information related to the sheet link are grouped (step S1601), and are converted into data as the sheet link (step S1602). A reason why the grouping is performed in step S1601 and specific processing will be described later. When “NO” is determined in step S1600, it is determined in step S1603 whether it is a coordinate link. As described above, although the coordinate link has various patterns, since the coordinate link is often present just beside an end point of a terminal component, it is determined whether a character is present just beside the end point of the terminal component (step S1603). Although specific processing in step S1603 is the same as that in step S800 in FIG. 8C, only a wiring name is targeted in step S800, whereas all characters present just beside the end point are targeted in step S1603. When “YES” is determined, data conversion is performed as a coordinate link (step S1604). When “NO” is determined in step S1603, it is determined in step S1605 whether it is a coordinate supplement link. In step S1605, as described above, since the coordinate supplement link is often a character surrounded by a circle or an ellipse (hereinafter, referred to as a “circle or ellipse character”), a circle or ellipse character is detected, and it is determined whether the character is surrounded by a circle or an ellipse (step S1605). A method for detecting the circle or ellipse character will be described later. When “YES” is determined, data conversion is performed as the coordinate supplement link (step S1606). When “NO” is determined, since the character does not correspond to any one of the sheet link, the coordinate link, and the coordinate supplement link, the processing ends directly. The output data includes at least character information and coordinate information on a link sign area.

### Grouping Method in Step S1601

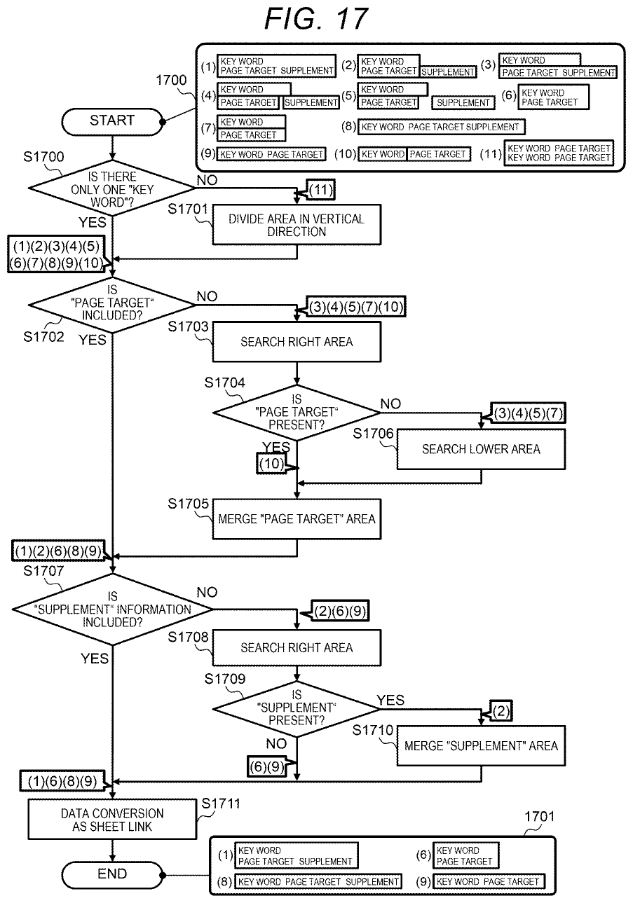

Next, a sheet link grouping method by the link sign detection unit 1200 in step S1601 will be described with reference to FIG. 17. First, a reason why grouping is performed such that necessary information for converting a sheet link into data is one character area will be described. The sheet link often includes a plurality of elements, and for example, a case where the sheet link includes three elements “key word”, “page target”, and “supplement” is considered. Here, the “key word” is a predetermined character of a sheet link such as “page” or “sheet”, the “page target” is a character designating a page target such as “page number” or “sheet name”, and the “supplement” is a character representing supplement information such as “to” or “from” indicating an input or output relationship. In this case, when the sheet link is described in drawing data, if a method for describing the sheet link changes depending on the drawing designer, a plurality of detection patterns of three elements output from the drawing component detection unit 103 are generated depending on a positional relationship among the elements (for example, whether the elements are described in one line or two lines, whether a line feed is performed, whether the three elements are collectively described in one character area or in different areas), whether “supplement” information is included, or the like. For example, there are 11 patterns as shown for various detection patterns 1700 of the sheet link in FIG. 17. Since the sheet link is a character indicating a “page” including a connection target, it is necessary to group at least the “key word” and the “page target” into one character area in order to have a function as the sheet link. A reason why the sheet links are grouped has been described above.

Hereinafter, the method for grouping the sheet links will be described with reference to a flowchart shown in FIG. 17. FIG. 17 is a flow of inputting a sheet link detection pattern and outputting a result of grouping at least the “key word” and the “page target” as one character area. As a specific example, an example in which 11 patterns as the detection patterns 1700 are grouped into a grouped pattern 1701 will be described. In FIG. 17, each pattern is numbered, and how each pattern is separated is shown by a speech bubble. First, it is determined whether there is one predetermined “key word” (step S1700). When “NO” is determined, a character area is divided in a vertical direction by the number of included “key words” (step S1701). Next, it is determined whether the “page target” is included (step S1702). In a determination method in step S1702, it is determined whether a character other than the “key word” is included. When “NO” is determined in step S1702, since the “page target” is often present in a right area or a lower area with respect to a “key word” area, the search is sequentially performed for each area. First, the search is performed in a rightward direction from a right side of the “key word” area (step S1703). Hereinafter, a search range may be determined as desired, but when the search range is determined according to a feature of a positional relationship among the areas, grouping accuracy is improved. For example, in a pattern (10) in which the “page target” is present in the right area of the “key word” shown in the drawing, a “page target” area is adjacent by 1 pt. In this case, in order to avoid erroneously grouping with an unnecessary character present therearound, the search range is preferably set to a right area of 1 pt. It is determined whether there is a “page target” area (step S1704), and when “YES” is determined in step S1704, the “key word” area and the “page target” area are merged (step S1705), and the area and character data are updated. When “NO” is determined in step S1704, a lower area is searched below a lower side of the “key word” area (step S1706). For example, when the “page” area is often present one line below the lower side of the “key word” area, the search range at this time is set to be an area lower than the “key word” area by 0.5 times in the vertical direction in order to avoid erroneously grouping with a character close to a lower side of a “page” area. After step S1706, merge processing with the “page target” area in step S1705 is executed. At this time, in addition to the “page target” area, character areas present in the search range (that is, areas are partially shared) may be merged together, and for example, in a pattern (4), since the “supplement” area is present in the search range lower than the lower side of the “key word” area by 0.5 times in the vertical direction, the “supplement” area may be merged together. Next, it is determined whether “supplement” information is included (S1707). In the determination method in S1707, since the characters used in the “supplement” information are often the same based on a predetermined rule, it is determined whether the characters used in the predetermined rule are included. For example, when input and output information such as “to” and “from” is used as the “supplement” information, it is determined whether “to” and “from” are included. When “NO” is determined in step S1707, a right area from a right side of an area including the “key word” and the “page target” is searched (step S1708). This is because the “supplement” area is often present only in the right area. For example, when the “supplement” area is often present within 0.3 times the area including the “key word” and the “page target” in a horizontal direction, the search range at this time is set to be the right area from the right side thereof by 0.3 times in the horizontal direction in order to avoid erroneously grouping with an unnecessary character present therearound. After step S1708, it is determined whether the “supplement” area is present (step S1709), and when “YES” is determined in step S1709, the area including “key word” and “page target” and the “supplement” area are merged (step S1710). Finally, in step S1711, the grouped character areas and character information are updated, converted into data as the sheet link, and the processing ends. When the above processing flow is completed, since at least the “key word” and the “page target” are finally grouped into one character area, the character area and the character information can be registered as the sheet link. The sheet link grouping method by the link sign detection unit 1200 in step S1601 has been described above.

### In-table Sheet Link Registration Method by Link Sign Detection Unit 1200

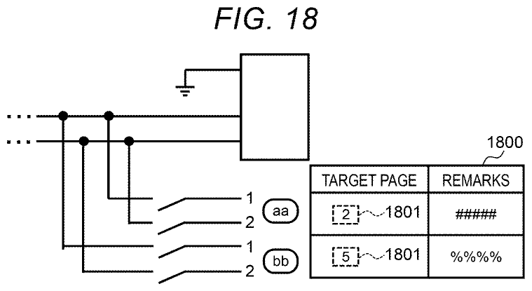

Next, an in-table sheet link registration method by the link sign detection unit 1200 will be described with reference to FIG. 18. In step S1600 in the flowchart shown in FIG. 16, when it is determined whether the predetermined key word such as “sheet” or “page” is included in the character information, an item name of a table included in the drawing data may correspond. In this case, at least a part of each cell area in a column with the item name is registered as a sheet link. For example, in a case of FIG. 18, an example is shown in which a page number including a connection target in the vicinity of an end point of a terminal component is described in a table 1800, and since a column with an item name “target page” corresponds to a sheet link indicating a “page” including the connection target, a cell including “2” and a cell including “5” in the “target page” column are registered as sheet links 1801. When carrying out the above, although not shown in FIG. 12, the drawing component detection unit 103 includes a table detection unit that detects a table from the drawing data 102. Data output from the table detection unit includes coordinates of a table area and each cell area, each item name, and character information included in each cell. The in-table sheet link registration method has been described above.

### Method for Detecting Circle or Ellipse Character by Link Sign Detection Unit 1200 in Step S1605

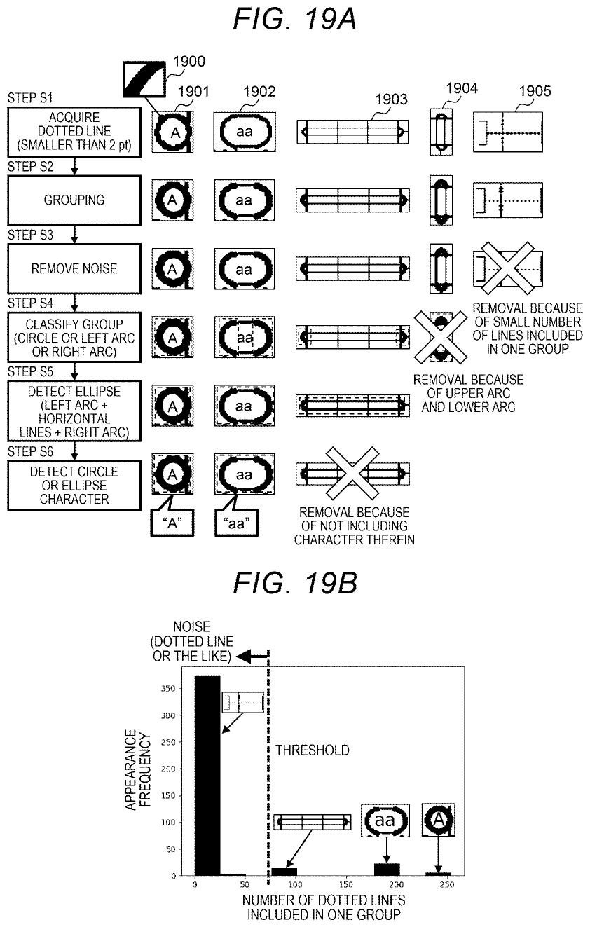

Next, a method for detecting a circle or ellipse character for conversion into coordinate supplement link data by the link sign detection unit 1200 in step S1605 will be described with reference to FIG. 19. As described above, a coordinate supplement link is characterized by being surrounded by a circle or an ellipse. Generally, when CAD drawing data is converted into PDF drawing data, a circle or an ellipse is drawn based on a Bezier curve, but depending on the drawing data, drawing may be performed by a set of dotted lines (for example, a set 1900 of dotted lines shown in FIG. 19A) instead of the Bezier curve due to a difference in a drawing method by a CAD designer. Therefore, in converting a coordinate supplement link into data, it is necessary to appropriately detect a circle or ellipse character even when arcs constituting a circle or ellipse are drawn by a set of dotted lines. Hereinafter, the method for detecting the circle or ellipse character when a curve is drawn by a set of dotted lines will be described with reference to detection steps (steps S1 to S6) shown in FIG. 19A. First, a dotted line included in the drawing data is acquired (step S1). Here, the dotted line refers to a line of a determined length or less, and for example, a line of 2 pt or less is the dotted line. At this time, among the acquired dotted lines, in addition to the dotted lines constituting a circle character 1901 or an ellipse character 1902 as a detection target, noise of an arc (dotted line noise 1903 and dotted line noise 1904) included in a drawing sign, and a square and a wiring formed by a dotted line (dotted line noise 1905) is also acquired. The noise is removed in step S3 and thereafter. Next, a distance between centers of the dotted lines is included in a range of a predetermined threshold (for example, a threshold of 2 pt in which a line used in step S1 is regarded as a dotted line), and the dotted lines closely adjacent to each other are grouped so that the closely adjacent dotted lines can be treated as a dotted line group (step S2). As the grouping method, it is possible to use a general clustering algorithm such as known density-based spatial clustering of applications with noise (DBSCAN). Next, among the above dotted line noise (1903, 1904, and 1905), the dotted line noise 1905 including the square and the wiring formed by the dotted line, having a highest appearance frequency, is removed (step S3). Specifically, a dotted line group having the number of dotted lines smaller than a predetermined threshold is removed based on the number of dotted lines included in one group. A method for determining the threshold will be described later. Next, in order to detect the circle or ellipse, the dotted line group is classified into any one of a circle, a left arc, and a right arc (step S4). Here, the “circle” and “left arc and right arc” can be classified according to a vertical and horizontal aspect ratio of a circumscribing rectangle. The left arc and the right arc can be classified by determining which of vertical lines in the −X direction and the +X direction includes a dotted line among the vertical lines constituting the circumscribing rectangle. A dotted line included in a vertical line close to the −X direction is the left arc, and a dotted line included in a vertical line close to the +X direction is the right arc. By classifying the dotted line groups, it is possible to remove the dotted line noise 1904 including an upper arc and a lower arc. Next, an ellipse is detected (step S5). Since the ellipse includes a left arc, two horizontal lines, and a right arc, a pattern having the above combination is detected. Specifically, the ellipse can be detected by detecting a horizontal line that shares a starting point with a left arc, detecting a right arc that shares an ending point with the horizontal line, and detecting a horizontal line that shares an ending point with the left arc and a starting point with the right arc. Since the “circle” can be detected in step S4 and the “ellipse” can be detected in step S5, finally, merge processing with a character area included in the circle or ellipse is performed to detect a circle or ellipse character including character information (step S6). Here, it is possible to remove the dotted line noise 1903 that is an ellipse but does not include character information therein. By the above detection steps (steps S1 to S6), it is possible to appropriately detect the circle or ellipse character and to convert the coordinate supplement link into data.

Next, a method for determining a threshold for removing the dotted line noise 1905 including the square and the wiring formed by the dotted line in step S3 among the detection steps will be described with reference to FIG. 19B. The threshold can be determined based on a relationship between the number of dotted lines included in one group and an appearance frequency of the group. FIG. 19B is an example of a histogram showing a relationship between the number of dotted lines included in one group in drawing data in one page and an appearance frequency of the dotted line group. For example, according to the histogram in FIG. 19B, the appearance frequency of the dotted line group in which the number of dotted lines included in one group is in a range of 0 to 25 is 300 or more, but a possibility that several hundred coordinate supplement links are included in the drawing data in one page is low. Therefore, most of the noise can be removed when the threshold is set such that the dotted line group in the range of 0 to 25 can be removed and the dotted line group in a range of 75 to 100 that may include an arc drawn by a set of dotted lines can be left (the threshold in the drawing is 70). Although the method for determining the threshold based on a rule has been described above, the threshold can be calculated more efficiently by automatically calculating the threshold using a known K-means method or the like.

### Operation of Terminal Component Connection Information Generation Unit 1201

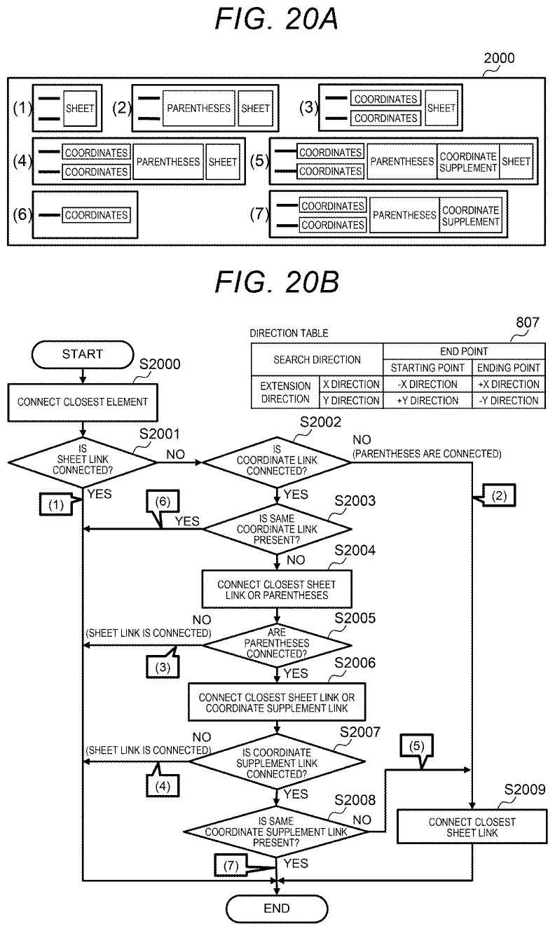

Next, an operation of the terminal component link sign connection information generation unit 1201 will be described with reference to FIGS. 20A and 20B. The terminal component link sign connection information generation unit 1201 connects a terminal component and a link sign and attaches information on a “page” and “coordinates” where a connection target is present to the terminal component. Here, an example of connecting a terminal wiring to a link sign will be described. A positional relationship pattern 2000 for the terminal wiring and the link sign includes a plurality of patterns based on combinations of the link sign and parentheses. In this case, the parentheses are drawing signs described such that the designer can know a range of associated characters on the drawing data at a glance, and are a set of lines having at least a U shape, which is present beside an end point of the terminal wiring. The parentheses data is output from the drawing sign detection unit 107, and includes at least a unique drawing sign name, coordinate information, and a page number. The positional relationship pattern 2000 for the terminal wiring and the link sign described above includes, for example, seven patterns having a coordinate link, a coordinate supplement link, a sheet link, and parentheses alone as components or a combination thereof as shown in FIG. 20A. Among the seven patterns, patterns (1) to (5) refer to patterns having connection information between pages, and patterns (6) and (7) refer to patterns having connection information in a page. The patterns (patterns (1) to (5)) having the connection information between pages each include a sheet link, and information on a “page” where a connection target is present is attached from the sheet link. The patterns (patterns (6) and (7)) having the connection information in the page are characterized by including the same coordinate link or coordinate supplement link in the same page, and information on a “page” where a connection target is present is attached to the page where the coordinate link or the coordinate supplement link is present. Although not shown in the drawing, particularly regarding the coordinate supplement link and the sheet link, a position may be shifted in a direction perpendicular to an extension direction of the terminal wiring in description due to a limitation in description space when the designer creates the drawing data.

Hereinafter, a method for appropriately connecting a terminal wiring to a link sign will be described with reference to a connection flowchart shown in FIG. 20B. A case where the positional relationship pattern 2000 for the terminal wiring and the link sign shown in FIG. 20A is appropriately connected will be described as an example. In the method, since there is a pattern in which a position is shifted in the direction perpendicular to the extension direction of the terminal wiring, elements close to each other are sequentially connected from the terminal wiring. In addition, since each pattern is a combination of a coordinate link, a coordinate supplement link, a sheet link, and parentheses, the processing is branched according to a type of the connected elements. A connection direction follows the direction table 807 determined according to the “extension direction” and the “type of end point” from the end point of the terminal wiring described above.

FIG. 20B is a flow of inputting a terminal wiring and outputting data in which the terminal wiring is connected to a link sign and information on the link sign is attached to the terminal wiring. First, an element closest to an end point of the terminal wiring is searched for in a direction according to the direction table and connected (step S2000). Thereafter, when searching for and connecting the closest element, if the processing is executed after narrowing down elements to be connected in advance, erroneous connection can be prevented, and thus connection accuracy is improved. For example, in a case of step S2000, since elements close to the end point of the terminal wiring are a sheet link (pattern (1)), a coordinate link (patterns (3) to (7)), and parentheses (pattern (2)), a search target is the sheet link, the coordinate link, and the parentheses. Next, it is determined whether the connected element is a sheet link in order to separate the pattern (1) from other patterns (step S2001). When “YES” is determined in step S2001, since the pattern (1) is obtained, there is no more element to be connected, and the processing ends. When “NO” is determined in step S2001, it is determined whether the connected element is a coordinate link in order to separate the pattern (2) from other patterns (step S2002). When “NO” is determined in step S2002, the pattern (2) in which parentheses are connected is obtained, a sheet link closest to the parentheses is searched for and connected (step S2009), and the processing ends. On the other hand, when “YES” is determined in step S2002, it is searched for whether the same coordinate link is present in the same page in order to separate the pattern (6) from the patterns (3), (4), (5), and (7) (step S2003). When “YES” is determined in step S2003, connection in the pattern (6) is established, and the processing ends. When “NO” is determined in step S2003, since any one of the patterns (3), (4), (5), and (7) is obtained, a sheet link or parentheses closest to the coordinate link is searched for and connected (step S2004). Next, in order to separate the pattern (3) from the patterns (4), (5), and (7), it is determined whether the connected element is parentheses (step S2005). When “NO” is determined in step S2005, the pattern (3) in which a sheet link is connected is obtained, and the processing ends. When “YES” is determined in step S2005, since any one of the patterns (4), (5), and (7) is obtained, a sheet link or a coordinate supplement link closest to the parentheses is searched for and connected (step S2006). Next, it is determined whether the connected element is a coordinate supplement link in order to separate the pattern (4) from the patterns (5) and (7) (step S2007). When “NO” is determined in step S2007, since the pattern (4) in which a sheet link is connected is obtained, the processing ends. On the other hand, when “YES” is determined in step S2007, it is searched for whether the same coordinate supplement link is present in the same page in order to separate the pattern (5) from the pattern (7) (step S2008). When “YES” is determined in step S2008, since the pattern (7) is obtained, the processing ends. When “NO” is determined in step S2008, since the pattern (6) is obtained, the closest sheet link to a coordinate supplement link is searched for and connected (step S2009), and the processing ends. The operation by the terminal component link sign connection information unit 1201 and the method for connecting the terminal wiring to the link sign have been described above.

### Third Embodiment

A third embodiment of the invention provides drawing data in which a hyperlink to a connection target is assigned to a link sign. When a hyperlink is assigned to a character of drawing data on a screen of the terminal 101 and the hyperlink is tapped with an electronic pen or the like, page transition to a “page” including a connection target and “coordinates” of the connection target can be easily performed. Hereinafter, the third embodiment will be described in detail.

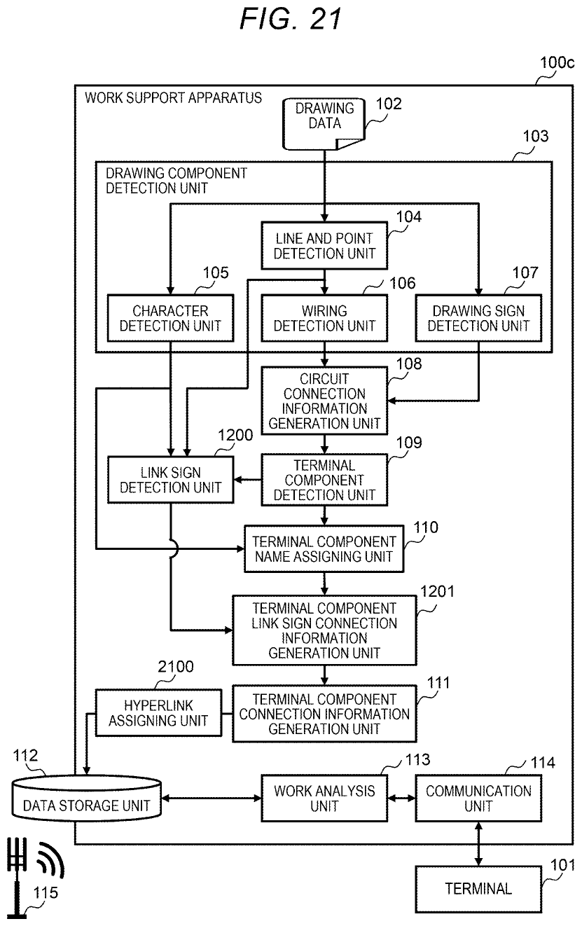

FIG. 21 is a functional block diagram of a work support apparatus 100c according to the third embodiment of the invention. Compared with the functional block diagram according to the first embodiment shown in FIG. 1 and the functional block diagram according to the second embodiment shown in FIG. 12, a hyperlink assigning unit 2100 is added. Hereinafter, the description of blocks common in processing to the first embodiment and/or the second embodiment will be omitted, and an operation of the work support apparatus 100c according to the third embodiment and a specific example of the hyperlink will be described in this order. Operation of Work Support Apparatus 100c

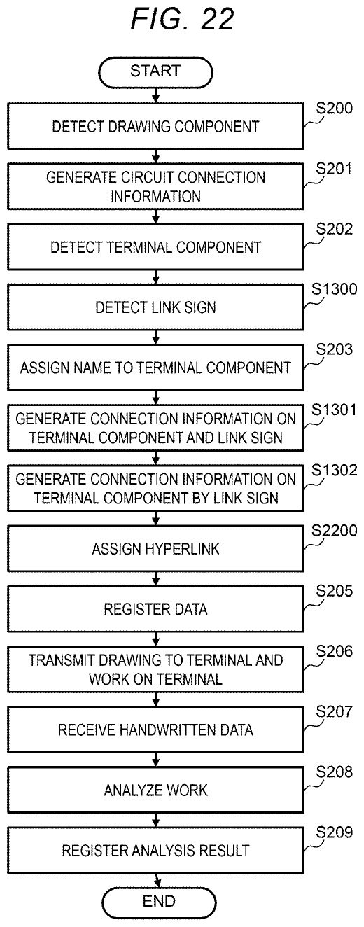

First, an operation of the work support apparatus 100c according to the third embodiment will be described using a flowchart shown in FIG. 22. Compared with the flowchart according to the second embodiment shown in FIG. 13, step S2200 of assigning a hyperlink is added. Hereinafter, the same steps as those according to the second embodiment are denoted by the same reference numerals, the description thereof will be omitted, and only different steps will be described below.

After searching for a corresponding link sign and generating connection information on a terminal component in step S1302, a hyperlink is assigned to a “page” having the connection target and “coordinates” of the connection target in a link sign area (step S2200). The operation different from that of the work support apparatus 100b according to the second embodiment, among main operations performed by the work support apparatus 100c according to the third embodiment, has been described above.

### Specific Examples of Assigning Hyperlink by Hyperlink Assigning Unit 2100

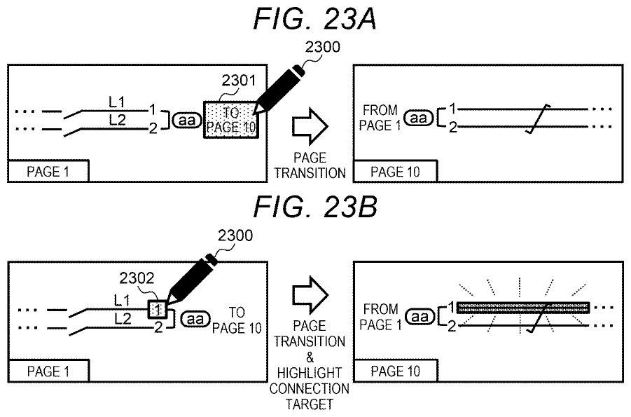

Next, specific examples of assigning a hyperlink by the hyperlink assigning unit 2100 will be described with reference to examples of drawing data shown in FIGS. 23A and 23B. FIG. 23A shows an example of drawing data in which a hyperlink is assigned to a sheet link. Since the sheet link has information on a “page” including a connection target, when a hyperlink having the “page” information (a hyperlink 2301 assigned to a sheet link in FIG. 23A) is assigned and the hyperlink 2301 is tapped on a screen of the terminal 101 with an electronic pen 2300 or the like, it is possible to immediately transition to the corresponding page. By assigning the hyperlink to the sheet link in this manner, it is possible to shorten the time required for turning pages during work, which can be useful for work efficiency. Here, the “page” information to be attached to the hyperlink may be either a page of the same file or a page of another file. When the “page” information to be attached to the hyperlink is the page of the other file, the hyperlink assigning unit 2100 attaches the hyperlink to the sheet link by identifying a directory in which the file is present.

FIG. 23B shows an example of drawing data in which a hyperlink is assigned to a coordinate link. The coordinate link has information on “coordinates” of a connection target, and the hyperlink (a hyperlink 2302 assigned to a coordinate link in FIG. 23B) having information on a “page” and “coordinates” is assigned together with information on a coordinate supplement link and a sheet link connected to the coordinate link, whereby when the hyperlink is tapped on the screen of the terminal 101 with the electronic pen 2300 or the like, transition to the page and the connection target can be highlighted by highlighting or the like. By highlighting the connection target in addition to the page transition in this manner, in addition to improving work efficiency, the connection target can be clearly shown, which can be used for preventing a work error. The specific examples of assigning the hyperlink by the hyperlink assigning unit 2100 have been described above.

The Embodiments of the Invention Described Above are Summarized as Follows.

(1) A work support apparatus (100a, 100b, 100c) includes the line and point detection unit 104, the drawing sign detection unit 107, the wiring detection unit 106, the character detection unit 105, the circuit connection information generation unit 108, and the terminal component detection unit 109. The line and point detection unit 104 acquires drawing data in which a circuit indicating a connection relationship between devices is described by a character, a line, and a point, and detects the line and the point based on the drawing data. The drawing sign detection unit 107 detects a drawing sign constituting the circuit. The wiring detection unit 106 detects a wiring connecting the drawing signs based on information on the line and point. The character detection unit 105 detects the character. The circuit connection information generation unit 108 generates circuit connection information by extracting information on contact of the drawing sign with the wiring on the drawing data based on coordinate data on the drawing sign and the wiring included in the same page of the drawing data. Since the circuit connection information in the same page and over pages of the drawing data is generated, the terminal component detection unit 109 detects, as a terminal component, a wiring or a first drawing sign that is not connected to a second drawing sign at least at one end based on the circuit connection information generated by the circuit connection information generation unit 108. In this manner, the work support apparatus (100a, 100b, 100c) can detect a drawing component indicating a break based on the drawing data including line and character data and accurately generate connection information on the drawing component indicating the break. As a result, the work support apparatus (100a, 100b, 100c) can generate the circuit connection information over a plurality of pages as intended by a designer.

(2) The terminal component is a set of wirings including at least a first wiring, which is electrically equivalent to the first drawing sign that is not connected to the second drawing sign at least at one end, among the wirings included in the circuit connection information.

(3) The terminal component is a drawing sign connected to two or more arrows at other ends, tip ends of the arrows being not connected to the second drawing sign.

(4) The terminal component detection unit 109 executes attribute determination processing of determining whether the wiring sharing the drawing sign has an attribute indicating that the wiring is electrically equivalent to the drawing sign connected to the wiring, and outputting determination information, grouping the wiring sharing the drawing sign having the attribute into a wiring group, and outputting information on the wiring group, switching the wiring that is a target of the attribute determination processing of the drawing sign in the wiring group, and determining whether determination of whether all wirings included in the wiring group have the attribute is completed, and outputting determination information.

(5) The work support apparatus 100a further includes the terminal component name assigning unit 110, the terminal component connection information generation unit 111, and the data storage unit 112. The terminal component name assigning unit 110 identifies a correspondence relationship between the character present around the terminal component and the terminal component, and assigns information on the character corresponding to a component name to the terminal component. The terminal component connection information generation unit 111 identifies a wiring or drawing sign having the same component name as that of the terminal component to which the component name is assigned from a plurality of pages including a page where the terminal component is present, and generates connection information including first circuit connection information including the terminal component and second circuit connection information including the wiring or drawing sign having the same component name as the terminal component. The data storage unit 112 stores the connection information generated by the terminal component connection information generation unit 111.

(6) The terminal component name assigning unit 110 execute extending a line from an end of the terminal component in a first direction in which the terminal component extends, and outputting information on the character having a smallest distance from the extended line, and outputting information on the character sharing at least a part in width with the terminal component in a second direction orthogonal to the first direction.

(7) The terminal component connection information generation unit 111 executes outputting a result of searching for the wiring or drawing sign having the same component name as that of the terminal component in a first page including the terminal component, and outputting a result of searching for the wiring or drawing sign having the same component name as the terminal component in a second page having a page number different from a page number of the first page in an ascending order from the first page.

(8) The work support apparatus 100b further includes the link sign detection unit 1200, the terminal component name assigning unit 110, the terminal component link sign connection information generation unit 1201, the terminal component connection information generation unit 111, and the data storage unit 112. The link sign detection unit 1200 detects a link sign indicating a location where a connection target of the terminal component is present using any one of the character alone, or the character and the line and point, or the character and data on the terminal component. The terminal component name assigning unit 110 identifies a correspondence relationship with the character representing a component name present around the terminal component, and assigns the component name to the terminal component. The terminal component link sign connection information generation unit 1201 identifies a positional relationship between the terminal component and the link sign, and associates the link sign with the terminal component. The terminal component connection information generation unit 111 identifies a wiring or drawing sign having a second link sign paired with a first link sign of the terminal component from a plurality of pages including a page where the terminal component is present, and generates connection information including first circuit connection information including the terminal component having the first link sign and second circuit connection information including the wiring or drawing sign having the second link sign. The data storage unit 112 stores the connection information generated by the terminal component connection information generation unit 111.

(9) The first link sign has, as data, at least one of page information in which the second link sign is present or coordinate information identifying coordinates of the second link sign, and a page where the second link sign is present and the coordinates are uniquely determined by combining two pieces of information including the page information and the coordinate information.

(10) The link sign detection unit 1200 executes page link sign determination processing of outputting a result of determining whether a key word representing a page is included in information on the character in order to determine a page link sign having the page information in which the second link sign is present, grouping a plurality of the characters based on the information on the character including the key word, and outputting information on a character group, extending a line from an end of the terminal component in a first direction in which the terminal component extends, and outputting information on the character having a smallest distance from the extended line, in order to determine a coordinate link sign having the coordinate information identifying the coordinates of the second link sign, and outputting a result of determining whether the character is surrounded by a circle or an ellipse in order to determine the coordinate link sign.

(11) When the circle or ellipse surrounding the character is described as a set of dotted lines, the link sign detection unit 1200 further executes acquiring, as a dotted line, the line whose length is smaller than a first threshold among the lines included in the drawing data, and outputting information on the dotted line, grouping the dotted lines whose distance between the dotted lines is smaller than a second threshold among the dotted lines, and outputting information on a dotted line group, removing, as noise, the dotted line group whose number of dotted lines included in the dotted line group is smaller than a third threshold among the dotted line groups, outputting a result of classifying the dotted line group into any one of a circle, a left arc, and a right arc, detecting the ellipse including the left arc and the right arc, and outputting information on the ellipse, and executing synthesis processing with the character included inside the circle or ellipse, detecting a circle or ellipse character including information on the character, and outputting information on the circle or ellipse character.

(12) The link sign detection unit 1200 determines whether a key word indicating the link sign is included in an item name of a table present in the drawing data, and detects, as the link sign, at least a part of cell areas in a column or a row with the item name when the key word is included.

(13) Using the link sign and parentheses that are signs describing a range of the wiring or drawing sign related to the link sign as elements to be connected, the terminal component link sign connection information generation unit 1201 executes outputting information in which the element closest to an end of the terminal component is connected, determining a type of the connected element, narrowing down the elements to be connected according to the type of the connected element, and outputting information in which the element closest to the connected element is connected, and determination processing of determining whether the same element as the connected element is present in the same page, and outputting a determination result.

(14) The work support apparatus 100c further includes the hyperlink assigning unit 2100. The hyperlink assigning unit 2100 provides, as a hyperlink, at least one piece of data among page information in which the second link sign is present and coordinate information identifying coordinates of the second link sign to an area of the first link sign based on a result of generating connection information on the terminal component and the wiring or drawing sign.

(15) The work support apparatus (100a, 100b, 100c) further includes the communication unit 114 and the work analysis unit 113. The communication unit 114 transmits data to the terminal 101 and receives data from the terminal 101. The work analysis unit 113 acquires circuit connection information in the same page and over pages of the drawing data, and analyzes handwritten data obtained by a worker tracing the wiring and the drawing sign on the drawing data by a manually input line on the terminal 101, by matching the handwritten data with coordinates of the wiring and the drawing sign included in the circuit connection information in the same page and over pages of the drawing data.

The invention is not limited to the above embodiments, and can be implemented by using any configuration within a range not departing from the gist of the invention.

The above embodiments, examples, and modifications are merely examples, and the invention is not limited to these contents as long as the features of the invention are not impaired. Although various embodiments, examples, and modifications have been described above, the invention is not limited to contents thereof. Other aspects conceivable within the scope of the technical idea of the invention are also included within the scope of the invention.

The above drawings show control lines and information lines that are considered to be necessary for description, and do not necessarily show all the control lines and information lines in mounting. For example, it may be considered that almost all the configurations are actually interconnected.

An arrangement form of the various functional units, the various processing units, and the various databases of the work support apparatus (100a, 100b, 100c) described above is merely an example. The arrangement form of the various functional units, the various processing units, and the various databases can be changed to an optimal arrangement form from a viewpoint of performance, processing efficiency, communication efficiency, and the like of hardware and software provided in the work support apparatus (100a, 100b, 100c).

What is claimed is:

1. A work support apparatus comprising:
a line and point detection unit configured to acquire drawing data in which a circuit indicating a connection relationship between devices is described by a character, a line, and a point, and to detect the line and point based on the drawing data;
a drawing sign detection unit configured to detect a drawing sign constituting the circuit;
a wiring detection unit configured to detect a wiring connecting the drawing signs based on information on the line and point;
a character detection unit configured to detect the character;
a circuit connection information generation unit configured to generate circuit connection information by extracting information on contact of the drawing sign with the wiring on the drawing data based on coordinate data on the drawing sign and the wiring included in the same page of the drawing data; and
a terminal component detection unit configured to detect, as a terminal component, a wiring or first drawing sign that is not connected to a second drawing sign at least at one end based on the circuit connection information generated by the circuit connection information generation unit, since the circuit connection information in the same page and over pages of the drawing data is generated.

2. The work support apparatus according to claim 1, wherein
the terminal component is a set of the wirings including at least a first wiring, which is electrically equivalent to the first drawing sign that is not connected to the second drawing sign at least at one end, among the wirings included in the circuit connection information.

3. The work support apparatus according to claim 1, wherein
the terminal component is a drawing sign connected to two or more arrows at other ends, tip ends of the arrows being not connected to the second drawing sign.

4. The work support apparatus according to claim 2, wherein
the terminal component detection unit executes
attribute determination processing of determining whether the wiring sharing the drawing sign has an attribute indicating that the wiring is electrically equivalent to the drawing sign connected to the wiring, and outputting determination information,
grouping the wiring sharing the drawing sign having the attribute into a wiring group, and outputting information on the wiring group,
switching the wiring that is a target of the attribute determination processing of the drawing sign in the wiring group, and
determining whether determination of whether all wirings included in the wiring group have the attribute is completed, and outputting determination information.

5. The work support apparatus according to claim 1, further comprising:
a terminal component name assigning unit configured to identify a correspondence relationship between the character present around the terminal component and the terminal component, and to assign information on the character corresponding to a component name to the terminal component;
a terminal component connection information generation unit configured to identify a wiring or drawing sign having the same component name as the terminal component to which the component name is assigned from a plurality of pages including a page where the terminal component is present, and generate connection information including first circuit connection information including the terminal component and second circuit connection information including the wiring or drawing sign having the same component name as the terminal component; and
a data storage unit configured to store the connection information generated by the terminal component connection information generation unit.

6. The work support apparatus according to claim 5, wherein
the terminal component name assigning unit executes
extending a line from an end of the terminal component in a first direction in which the terminal component extends, and outputting information on the character having a smallest distance from the extended line, and
outputting information on the character sharing at least a part in width with the terminal component in a second direction orthogonal to the first direction.

7. The work support apparatus according to claim 5, wherein
the terminal component connection information generation unit executes
outputting a result of searching for the wiring or drawing sign having the same component name as the terminal component in a first page including the terminal component, and
outputting a result of searching for the wiring or drawing sign having the same component name as the terminal component in a second page having a page number different from a page number of the first page in ascending order from the first page.

8. The work support apparatus according to claim 1, further comprising:
a link sign detection unit configured to detect a link sign indicating a location where a connection target of the terminal component is present using any one of the character alone, or the character and the line and point, or the character and data on the terminal component;
a terminal component name assigning unit configured to identify a correspondence relationship with the character representing a component name present around the terminal component, and assign the component name to the terminal component;
a terminal component link sign connection information generation unit configured to identify a positional relationship between the terminal component and the link sign, and associate the link sign with the terminal component;
a terminal component connection information generation unit configured to identify a wiring or drawing sign having a second link sign paired with a first link sign of the terminal component from a plurality of pages including a page where the terminal component is present, and generate connection information including first circuit connection information including the terminal component having the first link sign and second circuit connection information including the wiring or drawing sign having the second link sign; and
a data storage unit configured to store the connection information generated by the terminal component connection information generation unit.

9. The work support apparatus according to claim 8, wherein
the first link sign has, as data, at least one of page information in which the second link sign is present or coordinate information identifying coordinates of the second link sign, and
a page where the second link sign is present and the coordinates are uniquely determined by combining two pieces of information including the page information and the coordinate information.

10. The work support apparatus according to claim 8, wherein
the link sign detection unit executes
page link sign determination processing of outputting a result of determining whether a key word representing a page is included in information on the character in order to determine a page link sign having the page information in which the second link sign is present,
grouping a plurality of the characters based on the information on the character including the key word, and outputting information on a character group,
extending a line from an end of the terminal component in a first direction in which the terminal component extends, and outputting information on the character having a smallest distance from the extended line, in order to determine a coordinate link sign having the coordinate information identifying the coordinates of the second link sign, and
outputting a result of determining whether the character is surrounded by a circle or an ellipse in order to determine the coordinate link sign.

11. The work support apparatus according to claim 10, wherein
when the circle or ellipse surrounding the character is described as a set of dotted lines, the link sign detection unit further executes
acquiring, as a dotted line, the line whose length is smaller than a first threshold among the lines included in the drawing data, and outputting information on the dotted line,
grouping the dotted lines whose distance between the dotted lines is smaller than a second threshold among the dotted lines, and outputting information on a dotted line group,
removing, as noise, the dotted line group whose number of dotted lines included in the dotted line group is smaller than a third threshold among the dotted line groups,
outputting a result of classifying the dotted line group into any one of a circle, a left arc, and a right arc,
detecting the ellipse including the left arc and the right arc, and outputting information on the ellipse, and
synthesis processing with the character included inside the circle or ellipse, detecting a circle or ellipse character including information on the character, and outputting information on the circle or ellipse character.

12. The work support apparatus according to claim 8, wherein
the link sign detection unit
determines whether a key word indicating the link sign is included in an item name of a table present in the drawing data, and
detects, as the link sign, at least a part of cell areas in a column or a row with the item name when the key word is included.

13. The work support apparatus according to claim 8,
wherein
using the link sign and parentheses that are signs describing a range of the wiring or drawing sign related to the link sign as elements to be connected, the terminal component link sign connection information generation unit executes
outputting information in which the element closest to an end of the terminal component is connected,
determining a type of the connected element,
narrowing down the elements to be connected according to the type of the connected element, and outputting information in which the element closest to the connected element is connected, and
determination processing of determining whether the same element as the connected element is present in the same page, and outputting a determination result.

14. The work support apparatus according to claim 8, further comprising:
a hyperlink assigning unit configured to provide, as a hyperlink, at least one piece of data among page information in which the second link sign is present and coordinate information identifying coordinates of the second link sign to an area of the first link sign based on a result of generating connection information on the terminal component and the wiring or drawing sign.

15. The work support apparatus according to claim 5, further comprising:
a communication unit configured to transmit data to a terminal and receives data from the terminal; and
a work analysis unit configured to acquire circuit connection information in the same page and over pages of the drawing data, and to analyze handwritten data obtained by a worker tracing the wiring and the drawing sign on the drawing data by a manually input line on the terminal, by matching the handwritten data with coordinates of the wiring and the drawing sign included in the circuit connection information in the same page and over pages of the drawing data.

16. The work support apparatus according to claim 8, further comprising: a communication unit configured to transmit data to a terminal and receives data from the terminal; and
a work analysis unit configured to acquire circuit connection information in the same page and over pages of the drawing data, and to analyze handwritten data obtained by a worker tracing the wiring and the drawing sign on the drawing data by a manually input line on the terminal, by matching the handwritten data with coordinates of the wiring and the drawing sign included in the circuit connection information in the same page and over pages of the drawing data.

17. A work support method comprising:
acquiring, by a computer, drawing data in which a circuit indicating a connection relationship between devices is described by a character, a line, and a point, and detecting, by a computer, the line and point based on the drawing data;
detecting, by the computer, a drawing sign constituting the circuit;
detecting, by the computer, a wiring connecting the drawing signs based on information on the line and point;
detecting the character by the computer;
generating, by the computer, circuit connection information by extracting information on contact of the drawing sign with the wiring on the drawing data based on coordinate data on the drawing sign and the wiring included in the same page of the drawing data; and
detecting, by the computer, as a terminal component, a wiring or first drawing sign that is not connected to a second drawing sign at least at one end based on the circuit connection information generated by the circuit connection information generation unit, since the circuit connection information in the same page and over pages of the drawing data is generated.
